(19) United States
(12) Patent Application Publication
(10) Pub. No.: US 2025/0364957 A1
(43) Pub. Date: Nov. 27, 2025

(54) POWER AMPLIFICATION SYSTEM, DIGITAL PREDISTORTION METHOD, AND DIGITAL PREDISTORTION CIRCUIT

(71) Applicant: Murata Manufacturing Co., Ltd., Nagaokakyo-shi (JP)

(72) Inventors: John HOVERSTEN, Waltham, MA (US); Ty Lewis, Waltham, MA (US); Yevgeniy Tkachenko, Waltham, MA (US); Muneharu Kato, Nagaokakyo-shi (JP); Takeshi Kogure, Nagaokakyo-shi (JP); Toshiki Matsui, Nagaokakyo-shi (JP)

(21) Appl. No.: 19/291,079

(22) Filed: Aug. 5, 2025

Related U.S. Application Data
(63) Continuation of application No. PCT/JP2024/002943, filed on Jan. 30, 2024.
(60) Provisional application No. 63/444,286, filed on Feb. 9, 2023.

(51) Int. Cl. H03F 1/32; H03F 3/24

(52) U.S. Cl. CPC H03F 1/3258; H03F 3/24; H03F 2200/102; H03F 2200/105; H03F 2200/451

(57) ABSTRACT

A power amplification system includes: a first power amplifier; an output switch circuit configured to output a power supply to the first power amplifier; a filter circuit that is to connect to a first path in a switchable manner, the first path providing the power supply from the output switch circuit to the first power amplifier; and a digital predistortion circuit configured to generate distortions in a first input signal of the first power amplifier. When the filter circuit is not connected to the first path, the digital predistortion circuit generates the distortions by using a first mathematical-expression model with the first parameter set. When the filter circuit is connected to the first path, the digital predistortion circuit generates the distortions by using a second mathematical-expression model with the second parameter set. The first and second parameter sets are at least partially different from each other.

### CROSS-REFERENCE TO RELATED APPLICATIONS

This application is a continuation of International Application No. PCT/JP2024/002943 filed on Jan. 30, 2024, which claims priority to U.S. Provisional Patent Application No. 63/444,286 filed on Feb. 9, 2023, the contents of each of which are hereby incorporated by reference in their entirety.

### TECHNICAL FIELD

The present disclosure relates to a power amplification system, a digital predistortion method, and a digital predistortion circuit.

### BACKGROUND

These days, with the application of a tracking technology to a power amplifier circuit, the power-added efficiency is being improved. U.S. Pat. No. 8,829,993 discloses a tracker circuit for D-ET (Digital Envelope Tracking) that supplies a power supply voltage which is varied to multiple discrete levels over time (hereinafter called multiple discrete voltages). U.S. Pat. No. 10,686,407 discloses a tracker circuit for SPT (Symbol Power Tracking) which supplies multiple discrete voltages.

### SUMMARY OF THE DISCLOSURE

In view of the foregoing, according to exemplary aspects of the present disclosure, when such multiple discrete voltages are supplied to a power amplifier, digital predistortion (DPD) can be employed to reduce nonlinear distortion which occurs when the power amplifier operates in a nonlinear region. By predistorting an input signal to be supplied to a power amplifier, DPD can reduce the nonlinear distortion occurring in the power amplifier. When multiple discrete voltages are supplied to the power amplifier, it is desirable to further reduce the nonlinear distortion.

Accordingly, the present disclosure provides a power amplification system, a digital predistortion method, and a digital predistortion circuit that are capable of reducing nonlinear distortion.

In an exemplary aspect, a power amplification system includes: a first power amplifier; an output switch circuit configured to selectively output at least one of multiple discrete voltages as a first power supply of the first power amplifier; a filter circuit that is to connect to a first path in a switchable manner, the first path providing the first power supply from the output switch circuit to the first power amplifier; and a digital predistortion circuit configured to generate first distortions in a first input signal of the first power amplifier. (i) When the filter circuit is not connected (also referred to as disconnected) to the first path, the digital predistortion circuit generates the first distortions in the first input signal by using a first mathematical-expression model with a first parameter set. (ii) When the filter circuit is connected to the first path, the digital predistortion circuit generates the first distortions in the first input signal by using a second mathematical-expression model with a second parameter set. The first parameter set and the second parameter set are at least partially different from each other.

In another exemplary aspect, a digital predistortion method includes: determining a mathematical-expression model for digital predistortion and a parameter set, based on an attenuation band of a variable filter circuit (also referred to as a filter circuit with a variable filtering characteristic) connected between an output switch circuit and a power amplifier, the output switch circuit selectively supplying at least one of multiple discrete voltages as a power supply of the power amplifier; and generating distortions in an input signal of the power amplifier by using the determined mathematical-expression model with the determined parameter set.

In another exemplary aspect, a digital predistortion circuit is provided. (i) When a filter circuit that is to connect to a first path in a switchable manner is not connected to the first path, the first path being used for selectively supplying at least one of multiple discrete voltages to a first power amplifier, the digital predistortion circuit generates first distortions in a first input signal of the first power amplifier by using a first mathematical-expression model with a first parameter set. (ii) When the filter circuit is connected to the first path, the digital predistortion circuit generates the first distortions in the first input signal by using a second mathematical-expression model with a second parameter set. The first parameter set and the second parameter set are at least partially different from each other.

A power amplification system according to an exemplary aspect of the disclosure and other exemplary aspects of the disclosure can reduce nonlinear distortion.

### BRIEF DESCRIPTION OF THE DRAWINGS

FIG. 1A is a graph illustrating an example of the transition of a power supply voltage in an APT (Average Power Tracking) mode;

FIG. 1B is a graph illustrating an example of the transition of a power supply voltage in an A-ET (Analog Envelope Tracking) mode;

FIG. 1C is a graph illustrating an example of the transition of a power supply voltage in a D-ET mode;

FIG. 2 is a circuit diagram of a communication apparatus according to a first embodiment;

FIG. 3 is a circuit diagram of tracker circuitry according to the first embodiment;

FIG. 4 is a flowchart illustrating a DPD method according to the first embodiment;

FIG. 5 is a partial circuit diagram of tracker circuitry according to a first modified example of the first embodiment;

FIG. 6 is a partial circuit diagram of tracker circuitry according to a second modified example of the first embodiment;

FIG. 7 is a partial circuit diagram of tracker circuitry according to a third modified example of the first embodiment;

FIG. 8 is a circuit diagram of a communication apparatus according to a second embodiment;

FIG. 9 is a circuit diagram of tracker circuitry according to the second embodiment;

FIG. 10 is a partial circuit diagram of tracker circuitry according to a first modified example of the second embodiment;

FIG. 11 is a partial circuit diagram of tracker circuitry according to a second modified example of the second embodiment;

FIG. 12 is a circuit diagram of a communication apparatus according to a third embodiment;

FIG. 13 is a circuit diagram of tracker circuitry according to the third embodiment; and

FIG. 14 is a partial circuit diagram of tracker circuitry according to a first modified example of the third embodiment.

### DETAILED DESCRIPTION OF THE EMBODIMENTS

Embodiments of the disclosure will be described below in detail with reference to the drawings. All the embodiments described below illustrate general or specific examples. Numerical values, configurations, materials, elements, and positions and connection states of the elements illustrated in the following embodiments are only examples and are not intended to limit the disclosure.

The drawings are only schematically shown and are not necessarily precisely illustrated. For the sake of representing the disclosure, the drawings are illustrated in an exaggerated manner or with omissions or the ratios of elements in the drawings are adjusted. The shapes, positional relationships, and ratios of elements in the drawings may be different from those of the actual elements. In the drawings, substantially identical elements are designated by like reference numeral, and it is possible that an explanation of such elements be not repeated or be merely simplified.

In the circuit configurations of the disclosure, the phrase “A is connected to B” includes, not only the meaning that A is directly connected to B using a connecting terminal and/or a wiring conductor, but also the meaning that A is electrically connected to B via another circuit element. The phrase “A is directly connected to B” can mean that A is directly connected to B using a connecting terminal and/or a wiring conductor without another circuit element interposed between A and B. The phrase “C is connected between A and B” can mean that one end of C is connected to A and the other end of C is connected to B and that C is connected in series with a path connecting A and B. The phrase “A path connecting A and B” can refer to a path constituted by a conductor which electrically connects A to B.

The phrase “A is connected to a path” includes, not only the meaning that one end of A is connected to one end of a path and the other end of A is connected to the other end of the path (hereinafter such a connection state may also be called “be connected in series with”), but also the meaning that one end of A is connected to a path and the other end of A is connected to a ground (hereinafter such a connection state may also be called “be shunt-connected to”). The phrase “A is connected to a path in a switchable manner” can mean that the connection between A and a path and the disconnection of A from the path can be switched between each other, that is, A is connected to the path via a switch. The phrase “A is connected to a path” can include the meaning that “A is connected to a path in a switchable manner”.

In the following description, the phrase “a terminal” can refer to a point at which a conductor within an element terminates. If the impedance of a conductor between elements is sufficiently low, a terminal can be interpreted, not as a single point, but as certain points on the conductor between the elements or as the entire conductor.

The phrase “Attenuation band of a filter circuit” can refer to a portion of a frequency spectrum attenuated by a filter circuit, and is defined as a frequency band in which output power is attenuated to be lower than maximum output power by 15 dB or greater.

Terms representing the relationship between elements, such as “being parallel” and “being vertical”, terms representing the shape of an element, such as “being rectangular”, and ranges of numerical values are not necessarily to be interpreted in an exact sense, but to be interpreted in a broad sense. That is, such terms and ranges also cover substantially equivalent ranges, such as about several percent of allowance.

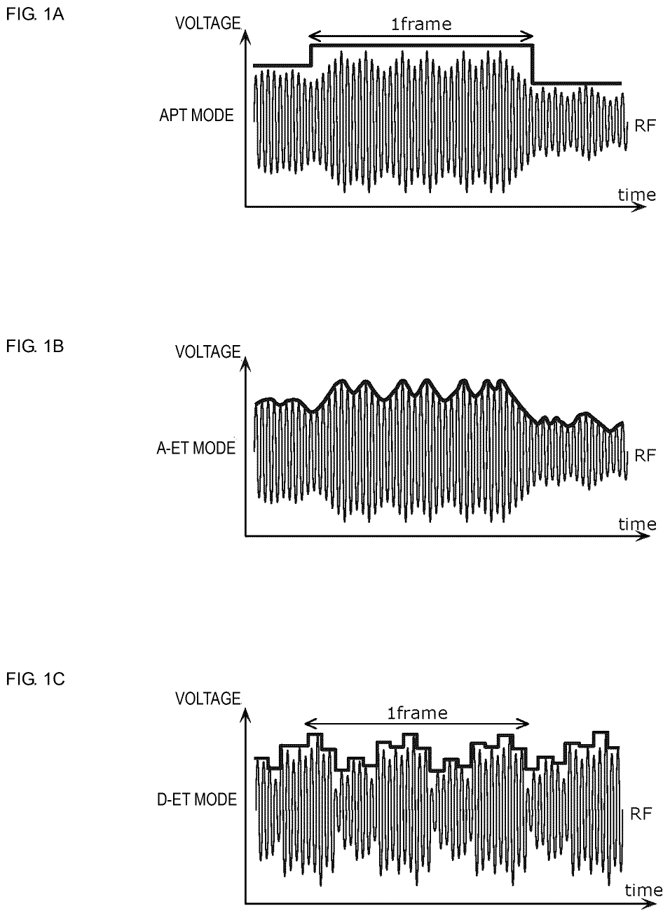

As a technology for amplifying a radio-frequency signal with high efficiency, a tracking mode in which a power supply voltage dynamically adjusted over time based on a radio-frequency signal is supplied to a power amplifier will first be discussed. The tracking mode is a mode in which the power supply voltage to be applied to a power amplifier is dynamically adjusted. There are several types of tracking modes. In this example, APT mode, A-ET mode, and D-ET mode will be explained below with reference to FIGS. 1A, 1B, and 1C, respectively. In FIGS. 1A through 1C, the horizontal axis indicates the time, and the vertical axis indicates the voltage. The thick solid line represents the power supply voltage, while the thin solid line (waveform) represents a modulated wave.

FIG. 1A is a graph illustrating an example of the transition of the power supply voltage in the APT mode. In the APT mode, based on average power, the power supply voltage is varied to multiple discrete voltage levels in units of frames. As a result, a power supply voltage signal forms a square wave.

A frame is a unit which forms a radio-frequency signal (modulated wave). For example, 5GNR (5th Generation New Radio) and LTE (Long Term Evolution) define that a frame includes ten subframes, each subframe includes plural slots, and each slot is constituted by plural symbols. The subframe length is 1 ms, and the frame length is 10 ms.

The mode in which the voltage level is varied in units of frames or in a larger unit based on average power is called the APT mode. The APT mode is distinguished from a mode in which the voltage level is varied in a unit (subframe, slot, or symbol, for example) smaller than a frame.

FIG. 1B is a graph illustrating an example of the transition of the power supply voltage in the A-ET mode. In the A-ET mode, the power supply voltage is continuously varied based on an envelope signal, so that the envelope of a modulated wave is tracked.

The envelope signal is a signal indicating the envelope of a modulated wave. The envelope value is represented by a square root of (I²+Q₂), for example. (I, Q) is a constellation point. The constellation point is a point of a digital modulated signal on a constellation diagram. (I, Q) is determined by a BBIC (Baseband Integrated Circuit) based on sending information, for example.

FIG. 1C is a graph illustrating an example of the transition of the power supply voltage in the D-ET mode. In the D-ET mode, based on an envelope signal, the power supply voltage is varied to multiple discrete voltage levels in one frame, so that the envelope of a modulated wave is tracked. As a result, a power supply voltage signal forms a square wave.

### First Exemplary Embodiment

A first exemplary embodiment will be described below.

### Circuit Configuration of Communication Apparatus 6

The circuit configuration of a communication apparatus 6 according to the first

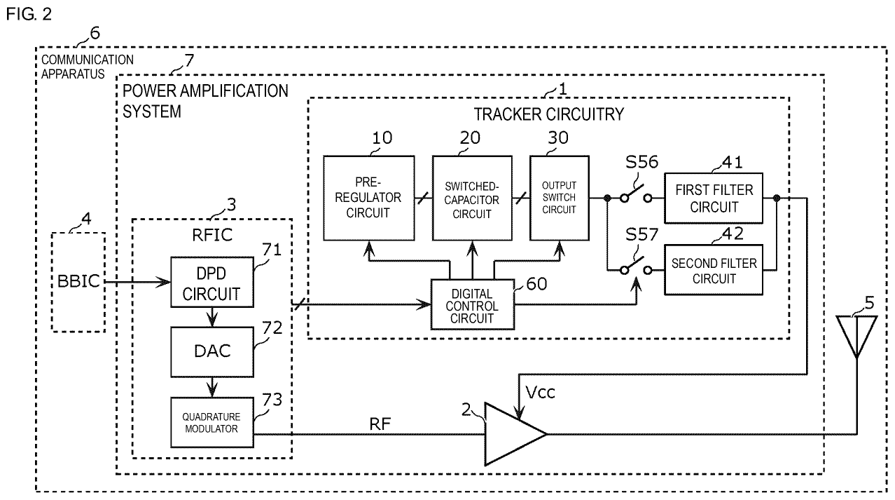

embodiment will first be discussed below with reference to FIG. 2. FIG. 2 is a circuit diagram of the communication apparatus 6 according to the first embodiment.

The circuit configuration shown in FIG. 2 is only an example. The communication apparatus 6 can be implemented by using any of a variety of circuit implementations and circuit technologies. Hence, the following explanation of the communication apparatus 6 is not to be interpreted in a limited manner.

The communication apparatus 6 in the first embodiment corresponds to UE (User Equipment) in a cellular network and is typically a cellular phone, a smartphone, a tablet computer, or a wearable device, for example. The communication apparatus 6 may be an IoT (Internet of Things) sensor device, a medical/healthcare device, a vehicle, an UAV (Unmanned Aerial Vehicle) (known as a drone), or an AGV (Automated Guided Vehicle). The communication apparatus 6 may serve as a BS (Base Station) in a cellular network.

As illustrated in FIG. 2, the communication apparatus 6 includes tracker circuitry 1, a power amplifier 2, a RFIC (Radio Frequency Integrated Circuit) 3, a BBIC 4, and an antenna 5. A power amplification system 7 includes the tracker circuitry 1, the power amplifier 2, and the RFIC 3.

Based on the tracking mode, the tracker circuitry 1 is able to supply multiple discrete voltages to the power amplifier 2 as a power supply voltage Vcc. In the first embodiment, as the tracking mode, the D-ET mode and the APT mode are used. However, the tracking mode to be used is not limited to these modes.

The power amplifier 2 is an example of a first power amplifier and is connected between the RFIC 3 and the antenna 5. The power amplifier 2 is also connected to the tracker circuitry 1. The power amplifier 2 is able to amplify a radio-frequency signal RF (an example of a first input signal) supplied from the RFIC 3 by using the power supply voltage Vcc supplied from the tracker circuitry 1.

The RFIC 3 is an example of a signal processing circuit that processes a radio-frequency signal. The RFIC 3 can receive a digital IQ signal from the BBIC 4 and supply the radio-frequency signal RF to the power amplifier 2. The internal configuration of the RFIC 3 will be discussed later.

The BBIC 4 is a baseband signal processing circuit that performs signal processing by using a frequency band lower than the radio-frequency signal RF. The BBIC 4 performs digital modulation on a bit sequence which represents an image signal for displaying an image and/or an audio signal for performing communication via a speaker, thereby generating a digital IQ signal. The generated IQ signal is supplied to the RFIC 3. The BBIC 4 may be omitted from the communication apparatus 6.

The antenna 5 sends the radio-frequency signal RF amplified by the power amplifier 2 to the outside of the communication apparatus 6. The antenna 5 may be omitted from the communication apparatus 6.

### 1.2 Internal Configuration of RFIC 3

The internal configuration of the RFIC 3 will be explained below with reference to FIG. 2. The RFIC 3 includes a DPD circuit 71, a DAC (Digital-to-Analog Converter) 72, and a quadrature modulator 73. The RFIC 3 may include a controller (not shown) for controlling the tracker circuitry 1. All or some of the functions of the RFIC 3 as the controller may be implemented outside the RFIC 3.

The DPD circuit 71 is able to predistort a digital IQ signal supplied from the BBIC 4 by using a mathematical-expression model for DPD. For example, the DPD circuit 71 can generate a predistorted digital IQ signal from the digital IQ signal. The predistorted digital IQ signal is supplied to the DAC 72. The DPD circuit 71 may skip DPD processing. In this case, the DPD circuit 71 can supply a digital IQ signal supplied from the BBIC 4 (that is, a digital IQ signal which is not predistorted) to the DAC 72.

The DAC 72 is able to convert the digital IQ signal supplied from the DPD circuit 71 into an analog IQ signal. The converted analog IQ signal is supplied to the quadrature modulator 73. The DAC 72 is not limited to a particular DAC, and a known DAC may be used.

The quadrature modulator 73 is able to generate a radio-frequency signal RF by performing quadrature modulation and up-conversion on the analog IQ signal supplied from the DAC 72. The generated radio-frequency signal RF is supplied to the power amplifier 2. The quadrature modulator 73 is not limited to a particular quadrature modulator, and a known quadrature modulator may be used.

The circuit configuration of the RFIC 3 is not limited to that shown in FIG. 2, which illustrates only an example of the circuit configuration of the RFIC 3. For instance, one or more or all of the DPD circuit 71, the DAC 72, and the quadrature modulator 73 may be provided outside the RFIC 3. For example, the DPD circuit 71 may be included in the BBIC 4.

A mathematical-expression model for DPD in the DPD circuit 71 will be explained below. In the first embodiment, as the mathematical-expression model for DPD, a mathematical-expression model with memory effects or a mathematical-expression model without memory effects may be used.

The memory effects refer to a change in the distortion in a power amplifier caused by past input signals. Accordingly, concerning a mathematical-expression model with memory effects, not only a change in the distortion caused by an original (current) input signal, but also that by past input signals, are formed into a model. Compared with a mathematical-expression model without memory effects, a mathematical-expression model with memory effects can reduce the nonlinear distortion but increases a calculation load.

A specific example of a mathematical-expression model without memory effects will be explained below.

$$x [ n ] = {\sum }_{i = 0}^{N - 1} {c}_{i} r [ n ] {\vert r [ n ] \vert}^{i} \qquad ( 1 )$$

$$x [ n ] : predistorted signal$$

$$r [ n ] : original input signal$$

$${c}_{i} : DPD coefficients$$

$$N : polynomial order$$

The above-described expression (1) is an example of a polynomial used in a mathematical-expression model without memory effects. The mathematical-expression model using expression (1) is called a memoryless polynomial model. In expression (1), regarding the original input signal r[n], the input signal and the exponentiated input signal are multiplied by each other. The polynomial order N and the DPD coefficient cᵢ, which are a parameter set of the memoryless polynomial model, can be determined empirically in advance and are prestored in a memory (not shown) included in the RFIC 3, for example.

In expression (1), it can be expected that the nonlinear distortion can be reduced if the polynomial order N is increased, but on the other hand, the calculation load may be elevated. Memory effects are not reflected in expression (1). Thus, there is a limitation on reducing the nonlinear distortion by using a memoryless polynomial model.

A specific example of a mathematical-expression model with memory effects will be explained below.

$$x [ n ] = {\sum }_{i = 1}^{N - 1} {\sum }_{q = 0}^{Q} {c}_{qi} r [ n - q ] {\vert r [ n - q ] \vert}^{i} \qquad ( 2 )$$

$$x [ n ] : predistorted signal$$

$$r [ n ] : original input signal$$

$${c}_{qi} : DPD coefficients$$

$$Q : memory depth$$

$$N : polynomial order$$

The above-described expression (2) is an example of a polynomial used in a mathematical-expression model with memory effects. The mathematical-expression model using expression (2) is called a MPM (Memory Polynomial Model). In expression (2), regarding each of the input signals r[n−q] from the past Q to the current time 0, the input signal and the exponentiated input signal are multiplied by each other. The polynomial order N, the memory depth Q, and the DPD coefficient C_{qi}, which are a parameter set of the MPM, can be determined empirically in advance and are prestored in a memory (not shown) included in the RFIC 3, for example.

In expression (2), it can be expected that the nonlinear distortion can be reduced if the polynomial order N and the memory depth Q are increased, but on the other hand, the number of parameters may be increased, the calculation load may be elevated, and the convergence properties when the DPD coefficient C_{qi} is determined may be decreased.

$$\begin{matrix}( 3 - 1 ) & \\ x [ n ] = {\sum }_{i = 1}^{N - 1} {\sum }_{q = 0}^{Q} {c}_{qi} r [ n - q ] {\vert r [ n - q ] \vert}^{i} & ( 3 )\end{matrix}$$

$$+ {\sum }_{i = 1}^{{N}_{d}} {\sum }_{m = 1}^{{M}_{d}} {\sum }_{q = 0}^{{Q}_{d}} {d}_{qmi} r [ n - q ] {\vert r [ n - q - m ] \vert}^{i} \qquad ( 3 - 2 )$$

$$+ {\sum }_{i = 1}^{{N}_{e}} {\sum }_{m = 1}^{{M}_{e}} {\sum }_{q = 0}^{{Q}_{e}} {e}_{qmi} r [ n - q ] {\vert r [ n - q + m ] \vert}^{i} \qquad ( 3 - 3 )$$

$$x [ n ] : predistorted signal$$

$$r [ n ] : original input signal$$

$${c}_{qi} , {d}_{qmi} , {e}_{qmi} : DPD coefficients$$

$$Q : sync memory depth$$

$$N : sync order$$

$${Q}_{d} : lag memory depth$$

$${M}_{d} : maximum lag$$

$${N}_{d} : lag order$$

$${Q}_{e} : lead memory depth$$

$${M}_{e} : maximum lead$$

$${N}_{e} : lead order$$

The above-described expression (3) is another example of a polynomial used in a mathematical-expression model with memory effects. The mathematical-expression model using expression (3) is called a GMP (Generalized Memory Polynomial Model). In expression (3), a sync term (3-1) is coupled with a Lag term (3-2) and a Lead term (3-3). The sync term (3-1) is the same as the term in expression (2) for MPM. In the Lag term (3-2), the input signal and the exponentiated past input signal are multiplied by each other. In the Lead term (3-3), the input signal and the exponentiated future input signal are multiplied by each other. The polynomial orders N, N_{d}, and Nₑ, the memory depths Q, and the DPD coefficients C_{qi}, d_{qmi}, and e_{qmi} of the individual terms, which are a parameter set of the GMP, can be determined empirically in advance and are prestored in a memory (not shown) included in the RFIC 3, for example.

In expression (3), it can be expected that the nonlinear distortion can be reduced if the memory depths Q, Q_{d}, and Qₑ of the individual terms and the cross widths Ma and Me are increased, but on the other hand, the number of parameters may be increased, the calculation load may be elevated, and the convergence properties when the DPD coefficients c_{qi}, d_{qmi}, and e_{qmi} are determined may be decreased.

The effect of reducing the nonlinear distortion becomes greater in ascending order of the memoryless polynomial model, MPM, and GMP, at the same time, however, the number of parameters becomes increased and the calculation load (namely, power consumption) becomes larger in the same order. That is, the GMP can reduce the nonlinear distortion by a greater level than the MPM and the memoryless polynomial model, and the MPM can reduce the nonlinear distortion by a greater level than the memoryless polynomial model. Conversely, the memoryless polynomial model can reduce the calculation load by a greater amount than the MPM and GMP. The MPM can reduce the calculation load by a greater amount than the GMP. Additionally, the memoryless polynomial model requires a smaller amount of memory for storing the parameters than the MPM and GMP. The MPM requires a smaller amount of memory for storing the parameters than the GMP.

The mathematical-expression model with memory effects is not restricted to MPM and GMP. That is, as the mathematical-expression model with memory effects, a mathematical expression different from the above-described expressions (2) and (3) may be used. The mathematical-expression model without memory effects is not restricted to the memoryless polynomial model. That is, as the mathematical-expression model without memory effects, a mathematical expression different from the above-described expression (1) may be used.

### 1.3 Circuit Configuration of Tracker Circuitry 1

The circuit configuration of the tracker circuitry 1 will be described below with reference to FIG. 2. The tracker circuitry 1 includes a pre-regulator circuit 10, a switched-capacitor circuit 20, an output switch circuit 30, first and second filter circuits 41 and 42, switches S56 and S57, and a digital control circuit 60.

The pre-regulator circuit 10 can convert an input voltage supplied from a DC power source (not shown) into a regulated voltage by using a power inductor. The pre-regulator circuit 10 includes a power inductor and a switch. The power inductor is an inductor used for stepping-up and/or stepping-down a DC (Direct Current) voltage. The power inductor is disposed in series with a DC path. The power inductor may be connected between the DC path and a ground (that is, the power inductor may be connected in parallel with the DC path). The pre-regulator circuit 10 configured as described above may also be called a magnetic regulator and/or a DC-to-DC converter.

The switched-capacitor circuit 20 includes plural capacitors and plural switches. The switched-capacitor circuit 20 is able to generate multiple discrete voltages having the respective discrete voltage levels from the voltage supplied from the pre-regulator circuit 10. The switched-capacitor circuit 20 may also be called a switched-capacitor voltage balancer.

The output switch circuit 30 can selectively output at least one of the multiple discrete voltages generated by the switched-capacitor circuit 20 to the power amplifier 2.

The first and second filter circuits 41 and 42 can attenuate noise from multiple discrete voltages to be supplied to the power amplifier 2. The first and second filter circuits 41 and 42 may also be called a pulse shaping network or a transition shaping filter. One of the first and second filter circuits 41 and 42 may be omitted from the tracker circuitry 1. To put it another way, only one of the first and second filter circuits 41 and 42 may be included in the tracker circuitry 1.

The switch S56 is an example of a first switch and is an ON/OFF switch for the first filter circuit 41. The switch S57 is an example of a second switch and is an ON/OFF switch for the second filter circuit 42. The switch S56 is connected between the output switch circuit 30 and the first filter circuit 41. The switch S57 is connected between the output switch circuit 30 and the second filter circuit 42. One of the switches S56 and S57 may be omitted from the tracker circuitry 1. In other words, only one of the switches S56 and S57 may be included in the tracker circuitry 1.

The digital control circuit 60 is able to control the pre-regulator circuit 10, switched-capacitor circuit 20, output switch circuit 30, and switches S56 and S57, based on a digital control signal from the RFIC 3.

It may be possible to omit some of the pre-regulator circuit 10, switched-capacitor circuit 20, output switch circuit 30, first and second filter circuits 41 and 42, switches S56 and S57, and digital control circuit 60 from the tracker circuitry 1. In one example, the pre-regulator circuit 10 may be omitted from the tracker circuitry 1. In another example, the first and second filter circuits 41 and 42 and the switches S56 and S57 may be omitted from the tracker circuitry 1. A desired combination of elements selected from the pre-regulator circuit 10, switched-capacitor circuit 20, output switch circuit 30, first and second filter circuits 41 and 42, and switches S56 and S57 may be integrated into a single circuit. Instead of the pre-regulator circuit 10 and the switched-capacitor circuit 20, the tracker circuitry 1 may include plural voltage supply circuits, as in U.S. Pat. No. 10,686,407. In this case, the output switch circuit 30 may be configured to select at least one of the plural voltage supply circuits.

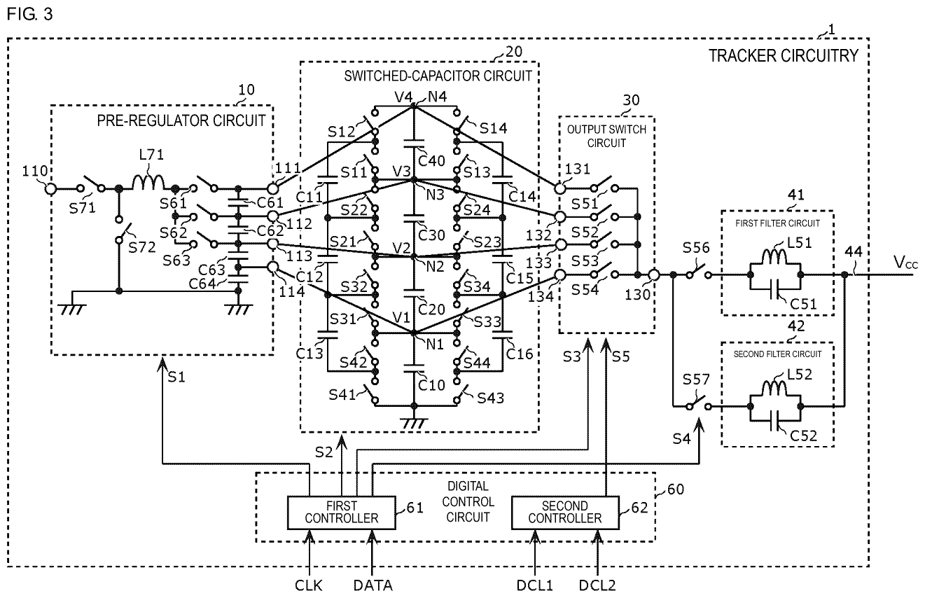

The circuit configurations of the individual circuits included in the tracker circuitry 1 will be described below with reference to FIG. 3. FIG. 3 is a circuit diagram of the tracker circuitry 1 according to the first embodiment.

The circuit configuration shown in FIG. 3 is only an example. The tracker circuitry 1 can be implemented by using any of a variety of circuit implementations and circuit technologies. Hence, the following explanation of the tracker circuitry 1 is not to be interpreted in a limited manner.

### 1.3.1 Circuit Configuration of Switched-Capacitor Circuit 20

The circuit configuration of the switched-capacitor circuit 20 will first be discussed below with reference to FIG. 3. As illustrated in FIG. 3, the switched-capacitor circuit 20 includes capacitors C11 through C16, capacitors C10, C20, C30, and C40, and switches S11 through S14, S21 through S24, S31 through S34, and S41 through S44. Energy and electric charge are input from the pre-regulator circuit 10 into the switched-capacitor circuit 20 via nodes N1 through N4 and are output from the switched-capacitor circuit 20 to the output switch circuit 30 via the nodes N1 through N4.

The capacitors C11 through C16 each serve as a flying capacitor (may also be called a transfer capacitor). That is, each of the capacitors C11 through C16 is used for stepping up or stepping down the regulated voltage supplied from the pre-regulator circuit 10. More specifically, the capacitors C11 through C16 transfer electric charge between the capacitors C11 through C16 and the nodes N1 through N4 so that voltages V1 through V4 (voltages with respect to a ground potential) which satisfy the relationship of V1:V2:V3:V4=1:2:3:4 can be maintained at the nodes N1 through N4, respectively. The voltages V1 through V4 correspond to multiple discrete voltages having the respective discrete voltage levels.

The capacitor C11 has two electrodes. One of the two electrodes of the capacitor C11 is connected to one end of the switch S11 and to one end of the switch S12. The other one of the two electrodes of the capacitor C11 is connected to one end of the switch S21 and to one end of the switch S22.

The capacitor C12 has two electrodes. One of the two electrodes of the capacitor C12 is connected to one end of the switch S21 and to one end of the switch S22. The other one of the two electrodes of the capacitor C12 is connected to one end of the switch S31 and to one end of the switch S32.

The capacitor C13 has two electrodes. One of the two electrodes of the capacitor C13 is connected to one end of the switch S31 and to one end of the switch S32. The other one of the two electrodes of the capacitor C13 is connected to one end of the switch S41 and to one end of the switch S42.

The capacitor C14 has two electrodes. One of the two electrodes of the capacitor C14 is connected to one end of the switch S13 and to one end of the switch S14. The other one of the two electrodes of the capacitor C14 is connected to one end of the switch S23 and to one end of the switch S24.

The capacitor C15 has two electrodes. One of the two electrodes of the capacitor C15 is connected to one end of the switch S23 and to one end of the switch S24. The other one of the two electrodes of the capacitor C15 is connected to one end of the switch S33 and to one end of the switch S34.

The capacitor C16 has two electrodes. One of the two electrodes of the capacitor C16 is connected to one end of the switch S33 and to one end of the switch S34. The other one of the two electrodes of the capacitor C16 is connected to one end of the switch S43 and to one end of the switch S44.

As a result of repeating a first phase and a second phase, a set of the capacitors C11 and C14, a set of the capacitors C12 and C15, and a set of the capacitors C13 and C16 can each complementarily perform charging and discharging.

More specifically, in the first phase, the switches S12, S13, S22, S23, S32, S33, S42, and S43 are ON. As a result, for example, one of the two electrodes of the capacitor C12 is connected to the node N3, the other one of the two electrodes of the capacitor C12 and one of the two electrodes of the capacitor C15 are connected to the node N2, and the other one of the two electrodes of the capacitor C15 is connected to the node N1.

In the second phase, the switches S11, S14, S21, S24, S31, S34, S41, and S44 are ON. As a result, for example, one of the two electrodes of the capacitor C15 is connected to the node N3, the other one of the two electrodes of the capacitor C15 and one of the two electrodes of the capacitor C12 are connected to the node N2, and the other one of the two electrodes of the capacitor C12 is connected to the node N1.

As a result of repeating the first phase and the second phase, when, for example, one of the capacitors C12 and C15 is being charged from the node N2, the other one of the capacitors C12 and C15 can discharge to the capacitor C30. That is, the capacitors C12 and C15 can complementarily perform charging and discharging.

As in the set of the capacitors C12 and C15, as a result of repeating the first phase and the second phase, a set of the capacitors C11 and C14 and a set of the capacitors C13 and C16 can also each complementarily perform charging and discharging.

The capacitors C10, C20, C30, and C40 each serve as a smoothing capacitor. That is, the capacitors C10, C20, C30, and C40 are respectively used for holding and smoothing the voltages VI through V4 at the nodes Nl through N4.

The capacitor C10 is connected between the node N1 and a ground. More specifically, one of two electrodes of the capacitor C10 is connected to the node N1, while the other one of the two electrodes of the capacitor C10 is connected to a ground.

The capacitor C20 is connected between the nodes N2 and N1. More specifically, one of two electrodes of the capacitor C20 is connected to the node N2, while the other one of the two electrodes of the capacitor C20 is connected to the node N1.

The capacitor C30 is connected between the nodes N3 and N2. More specifically, one of two electrodes of the capacitor C30 is connected to the node N3, while the other one of the two electrodes of the capacitor C30 is connected to the node N2.

The capacitor C40 is connected between the nodes N4 and N3. More specifically, one of two electrodes of the capacitor C40 is connected to the node N4, while the other one of the two electrodes of the capacitor C40 is connected to the node N3.

The switch S11 is connected between one of the two electrodes of the capacitor C11 and the node N3. More specifically, one end of the switch S11 is connected to one of the two electrodes of the capacitor C11. The other end of the switch S11 is connected to the node N3.

The switch S12 is connected between one of the two electrodes of the capacitor C11 and the node N4. More specifically, one end of the switch S12 is connected to one of the two electrodes of the capacitor C11. The other end of the switch S12 is connected to the node N4.

The switch S21 is connected between one of the two electrodes of the capacitor C12 and the node N2. More specifically, one end of the switch S21 is connected to one of the two electrodes of the capacitor C12 and to the other one of the two electrodes of the capacitor C11. The other end of the switch S21 is connected to the node N2.

The switch S22 is connected between one of the two electrodes of the capacitor C12 and the node N3. More specifically, one end of the switch S22 is connected to one of the two electrodes of the capacitor C12 and to the other one of the two electrodes of the capacitor C11. The other end of the switch S22 is connected to the node N3.

The switch S31 is connected between the other one of the two electrodes of the capacitor C12 and the node N1. More specifically, one end of the switch S31 is connected to the other one of the two electrodes of the capacitor C12 and to one of the two electrodes of the capacitor C13. The other end of the switch S31 is connected to the node N1.

The switch S32 is connected between the other one of the two electrodes of the capacitor C12 and the node N2. More specifically, one end of the switch S32 is connected to the other one of the two electrodes of the capacitor C12 and to one of the two electrodes of the capacitor C13. The other end of the switch S32 is connected to the node N2. That is, the other end of the switch S32 is connected to the other end of the switch S21.

The switch S41 is connected between the other one of the two electrodes of the capacitor C13 and a ground. More specifically, one end of the switch S41 is connected to the other one of the two electrodes of the capacitor C13. The other end of the switch S41 is connected to a ground.

The switch S42 is connected between the other one of the two electrodes of the capacitor C13 and the node N1. More specifically, one end of the switch S42 is connected to the other one of the two electrodes of the capacitor C13. The other end of the switch S42 is connected to the node N1. That is, the other end of the switch S42 is connected to the other end of the switch S31.

The switch S13 is connected between one of the two electrodes of the capacitor C14 and the node N3. More specifically, one end of the switch S13 is connected to one of the two electrodes of the capacitor C14. The other end of the switch S13 is connected to the node N3. That is, the other end of the switch S13 is connected to the other end of the switch S11 and to the other end of the switch S22.

The switch S14 is connected between one of the two electrodes of the capacitor C14 and the node N4. More specifically, one end of the switch S14 is connected to one of the two electrodes of the capacitor C14. The other end of the switch S14 is connected to the node N4. That is, the other end of the switch S14 is connected to the other end of the switch S12.

The switch S23 is connected between one of the two electrodes of the capacitor C15 and the node N2. More specifically, one end of the switch S23 is connected to one of the two electrodes of the capacitor C15 and to the other one of the two electrodes of the capacitor C14. The other end of the switch S23 is connected to the node N2. That is, the other end of the switch S23 is connected to the other end of the switch S21 and to the other end of the switch S32.

The switch S24 is connected between one of the two electrodes of the capacitor C15 and the node N3. More specifically, one end of the switch S24 is connected to one of the two electrodes of the capacitor C15 and to the other one of the two electrodes of the capacitor C14. The other end of the switch S24 is connected to the node N3. That is, the other end of the switch S24 is connected to the other end of the switch S11, to the other end of the switch S22, and to the other end of the switch S13.

The switch S33 is connected between the other one of the two electrodes of the capacitor C15 and the node N1. More specifically, one end of the switch S33 is connected to the other one of the two electrodes of the capacitor C15 and to one of the two electrodes of the capacitor C16. The other end of the switch S33 is connected to the node N1. That is, the other end of the switch S33 is connected to the other end of the switch S31 and to the other end of the switch S42.

The switch S34 is connected between the other one of the two electrodes of the capacitor C15 and the node N2. More specifically, one end of the switch S34 is connected to the other one of the two electrodes of the capacitor C15 and to one of the two electrodes of the capacitor C16. The other end of the switch S34 is connected to the node N2. That is, the other end of the switch S34 is connected to the other end of the switch S21, to the other end of the switch S32, and to the other end of the switch S23.

The switch S43 is connected between the other one of the two electrodes of the capacitor C16 and a ground. More specifically, one end of the switch S43 is connected to the other one of the two electrodes of the capacitor C16. The other end of the switch S43 is connected to a ground.

The switch S44 is connected between the other one of the two electrodes of the capacitor C16 and the node N1. More specifically, one end of the switch S44 is connected to the other one of the two electrodes of the capacitor C16. The other end of the switch S44 is connected to the node N1. That is, the other end of the switch S44 is connected to the other end of the switch S31, to the other end of the switch S42, and to the other end of the switch S33.

Based on a control signal S2, the ON/OFF state of a first set of switches including the switches S12, S13, S22, S23, S32, S33, S42, and S43 and that of a second set of switches including the switches S11, S14, S21, S24, S31, S34, S41, and S44 are switched therebetween in a complementary manner. More specifically, in the first phase, the switches included in the first set are ON, while the switches included in the second set are OFF. Conversely, in the second phase, the switches included in the first set are OFF, while the switches included in the second set are ON.

For example, in one of the first and second phases, the capacitors C11 through C13 charge the capacitors C10 through C40, and in the other one of the first and second phases, the capacitors C14 through C16 charge the capacitors C10 through C40. That is, the capacitors C10 through C40 are constantly charged from the capacitors C11 through C13 or from the capacitors C14 through C16. Hence, even if a current flows from the nodes N1 through N4 to the output switch circuit 30 at high speed, the nodes N1 through N4 are recharged quickly, thereby reducing potential variations at the nodes N1 through N4.

The switched-capacitor circuit 20 is operated in this manner so as to maintain a substantially equal voltage across each of the capacitors C10, C20, C30, and C40. More specifically, at the nodes N1 through N4 labeled with V1 through V4, respectively, the voltages V1 through V4 (voltages with respect to a ground potential) which satisfy the relationship of V1:V2:V3:V4=1:2:3:4 can be maintained. The voltage levels of the voltages V1 through V4 correspond to multiple discrete voltage levels that can be supplied to the output switch circuit 30 from the switched-capacitor circuit 20.

The voltage ratio (V1:V2:V3:V4) is not restricted to (1:2:3:4). For example, the voltage ratio (V1:V2:V3:V4) may be (1:2:4:8).

The configuration of the switched-capacitor circuit 20 is not restricted to that shown in FIG. 3, which illustrates only an example of the circuit configuration of the switched-capacitor circuit 20. Although the switched-capacitor circuit 20 shown in FIG. 3 is configured to supply four discrete voltages, the number of discrete voltages is not limited to four. The switched-capacitor circuit 20 may be configured to supply any number of multiple (two or more) discrete voltages. For example, if the switched-capacitor circuit 20 supplies two discrete voltages, it may include only at least the capacitors C12 and C15 and switches S21 through S24 and S31 through S34.

### 1.3.2 Circuit Configuration of Output Switch Circuit 30

The circuit configuration of the output switch circuit 30 will be described below with reference to FIG. 3. As illustrated in FIG. 3, the output switch circuit 30 includes input terminals 131 through 134, switches S51 through S54, and an output terminal 130.

The output terminal 130 is connected to the first and second filter circuits 41 and 42. The output terminal 130 is a terminal for supplying a power supply voltage selected from the voltages V1 through V4 to the power amplifier 2 via the first filter circuit 41 and/or the second filter circuit 42.

The input terminals 131 through 134 are connected to the nodes N4 through N1, respectively, of the switched-capacitor circuit 20. The input terminals 131 through 134 are terminals for receiving the voltages V4 through V1, respectively, from the switched-capacitor circuit 20.

The switch S51 is connected between the input terminal 131 and the output terminal 130. More specifically, the switch S51 has a terminal connected to the input terminal 131 and a terminal connected to the output terminal 130. With this connection configuration, the switch S51 is changed between ON and OFF based on a control signal S3, thereby making it possible to selectively connect the input terminal 131 to the output terminal 130 or disconnect the input terminal 131 from the output terminal 130.

The switch S52 is connected between the input terminal 132 and the output terminal 130. More specifically, the switch S52 has a terminal connected to the input terminal 132 and a terminal connected to the output terminal 130. With this connection configuration, the switch S52 is changed between ON and OFF based on the control signal S3, thereby making it possible to selectively connect the input terminal 132 to the output terminal 130 or disconnect the input terminal 132 from the output terminal 130.

The switch S53 is connected between the input terminal 133 and the output terminal 130. More specifically, the switch S53 has a terminal connected to the input terminal 133 and a terminal connected to the output terminal 130. With this connection configuration, the switch S53 is changed between ON and OFF based on the control signal S3, thereby making it possible to selectively connect the input terminal 133 to the output terminal 130 or disconnect the input terminal 133 from the output terminal 130.

The switch S54 is connected between the input terminal 134 and the output terminal 130. More specifically, the switch S54 has a terminal connected to the input terminal 134 and a terminal connected to the output terminal 130. With this connection configuration, the switch S54 is changed between ON and OFF based on the control signal S3, thereby making it possible to selectively connect the input terminal 134 to the output terminal 130 or disconnect the input terminal 134 from the output terminal 130.

The switches S51 through S54 are controlled to be ON mutually exclusively. That is, only one of the switches S51 through S54 is turned ON, while the remaining switches are turned OFF. This enables the output switch circuit 30 to output one voltage selected from the voltages V1 through V4.

The circuit configuration of the output switch circuit 30 is not limited to that shown in FIG. 3, which illustrates only an example of the circuit configuration of the output switch circuit 30. Among others, the switches S51 through S54 may be configured in any manner if they can selectively connect at least one of the four input terminals 131 through 134 to the output terminal 130. In one example, the output switch circuit 30 may include another switch between a set of the switches S51 through S53 and a set of the switch S54 and the output terminal 130. In another example, the output switch circuit 30 may include another switch between a set of the switches S51 and S52 and a set of the switches S53 and S54 and the output terminal 130.

If the switched-capacitor circuit 20 supplies two discrete voltages having the respective discrete voltage levels, the output switch circuit 30 may include only at least two of the switches S51 through S54.

### 1.3.3 Circuit Configuration of Pre-Regulator Circuit 10

The configuration of the pre-regulator circuit 10 will be described below with reference to FIG. 3. As illustrated in FIG. 3, the pre-regulator circuit 10 includes an input terminal 110, output terminals 111 through 114, switches S61 through S63 and S71 and S72, a power inductor L71, and capacitors C61 through C64.

The input terminal 110 is an input terminal for a DC voltage. That is, the input terminal 110 is a terminal for receiving an input voltage from a DC power source.

The output terminal 111 is an output terminal for the voltage V4. That is, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. That is, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. That is, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. That is, the output terminal 114 is a terminal for supplying the voltage VI to the switched-capacitor circuit 20. The output terminal 114 is connected to the node N1 of the switched-capacitor circuit 20.

The switch S71 is connected between the input terminal 110 and one end of the power inductor L71. More specifically, the switch S71 has a terminal connected to the input terminal 110 and a terminal connected to one end of the power inductor L71. With this connection configuration, as a result of the switch S71 being changed between ON and OFF based on a control signal S1, the switch S71 can selectively connect the input terminal 110 to one end of the power inductor L71 or disconnect the input terminal 110 from this end of the power inductor L71

The switch S72 is connected between one end of the power inductor L71 and a ground. More specifically, the switch S72 has a terminal connected to one end of the power inductor L71 and a terminal connected to a ground. With this connection configuration, as a result of the switch S72 being changed between ON and OFF based on the control signal S1, the switch S72 can selectively connect one end of the power inductor L71 to a ground or disconnect this end of the power inductor L71 from the ground.

The switch S61 is connected between the other end of the power inductor L71 and the output terminal 111. More specifically, the switch S61 has a terminal connected to the other end of the power inductor L71 and a terminal connected to the output terminal 111. With this connection configuration, as a result of the switch S61 being changed between ON and OFF based on the control signal S1, the switch S61 can selectively connect the other end of the power inductor L71 to the output terminal 111 or disconnect the other end of the power inductor L71 from the output terminal 111.

The switch S62 is connected between the other end of the power inductor L71 and the output terminal 112. More specifically, the switch S62 has a terminal connected to the other end of the power inductor L71 and a terminal connected to the output terminal 112. With this connection configuration, as a result of the switch S62 being changed between ON and OFF based on the control signal S1, the switch S62 can selectively connect the other end of the power inductor L71 to the output terminal 112 or disconnect the other end of the power inductor L71 from the output terminal 112.

The switch S63 is connected between the other end of the power inductor L71 and the output terminal 113. More specifically, the switch S63 has a terminal connected to the other end of the power inductor L71 and a terminal connected to the output terminal 113. With this connection configuration, as a result of the switch S63 being changed between ON and OFF based on the control signal S1, the switch S63 can selectively connect the other end of the power inductor L71 to the output terminal 113 or disconnect the other end of the power inductor L71 from the output terminal 113.

One of two electrodes of the capacitor C61 is connected to the switch S61 and to the output terminal 111. The other one of the two electrodes of the capacitor C61 is connected to the switch S62, to the output terminal 112, and to one of two electrodes of the capacitor C62.

One of the two electrodes of the capacitor C62 is connected to the switch S62, to the output terminal 112, and to the other one of the two electrodes of the capacitor C61. The other one of the two electrodes of the capacitor C62 is connected to a path connecting the switch S63, the output terminal 113, and one of two electrodes of the capacitor C63.

One of the two electrodes of the capacitor C63 is connected to the switch S63, to the output terminal 113, and to the other one of the two electrodes of the capacitor C62. The other one of the two electrodes of the capacitor C63 is connected to the output terminal 114 and to one of two electrodes of the capacitor C64.

One of the two electrodes of the capacitor C64 is connected to the output terminal 114 and to the other one of the two electrodes of the capacitor C63. The other one of the two electrodes of the capacitor C64 is connected to a ground.

The switches S61 through S63 are controlled to be ON mutually exclusively. That is, only one of the switches S61 through S63 is turned ON, while the remaining switches are turned OFF. Turning ON only one of the switches S61 through S63 enables the pre-regulator circuit 10 to vary the voltage to be supplied to the switched-capacitor circuit 20 between the voltage levels of the voltages V2 through V4.

The pre-regulator circuit 10 configured as described above is able to supply electric charge to the switched-capacitor circuit 20 via at least one of the output terminals 111 through 114.

If the input voltage is to be converted into only one regulated voltage, the pre-regulator circuit 10 may include only at least the switches S71 and S72 and the power inductor L71.

### 1.3.4 Circuit Configuration of First Filter Circuit 41 and Second Filter Circuit 42

The circuit configurations of the first and second filter circuits 41 and 42 according to the first embodiment will be explained below with reference to FIG. 3.

The first filter circuit 41 is connected in a switchable manner to a path 44 (an example of a first path), which connects the output switch circuit 30 and the power amplifier 2. More specifically, the first filter circuit 41 is connected between the output switch circuit 30 and the power amplifier 2 via the switch S56. The first filter circuit 41 includes a parallel circuit (LC parallel circuit) of an inductor L51 and a capacitor C51. One end of the parallel circuit of the inductor L51 and the capacitor C51 is connected to the output switch circuit 30 via the switch S56. The other end of the parallel circuit of the inductor L51 and the capacitor C51 is connected to the power amplifier 2. The first filter circuit 41 is not limited to an LC parallel circuit.

The second filter circuit 42 is connected to the path 44 in a switchable manner. More specifically, the second filter circuit 42 is connected between the output switch circuit 30 and the power amplifier 2 via the switch S57 in parallel with the first filter circuit 41. The second filter circuit 42 includes a parallel circuit of an inductor L52 and a capacitor C52. One end of the parallel circuit of the inductor L52 and the capacitor C52 is connected to the output switch circuit 30 via the switch S57. The other end of the parallel circuit of the inductor L52 and the capacitor C52 is connected to the power amplifier 2. The second filter circuit 42 is not limited to an LC parallel circuit.

The first filter circuit 41 connected in this manner is switched between ON and OFF by the switch S56, while the second filter circuit 42 connected in this manner is switched between ON and OFF by the switch S57. On the path 44, the first and second filter circuits 41 and 42 can thus change the attenuation band of a band elimination filter used for removing noise from multiple discrete voltages. That is, the first and second filter circuits 41 and 42 function as a variable filter circuit that can switch between multiple attenuation bands.

Under the opening/closing control of the switches S56 and S57, the first and second filter circuits 41 and 42 of the first embodiment can implement three types of band elimination filters indicated by the following modes (i), (ii), and (iii).
(i) The switch S56 is closed and the switch S57 is opened, so that the first filter circuit 41 is connected to the path 44 and the second filter circuit 42 is not connected to the path 44. Then, on the path 44, the first filter circuit 41 functions as a band elimination filter, while the second filter circuit 42 does not function as a band elimination filter.
(ii) The switches S56 and S57 are both closed, so that the first filter circuit 41 and the second filter circuit 42 are both connected to the path 44. Then, on the path 44, the first and second filter circuits 41 and 42 both serve as a band elimination filter.
(iii) The switch S56 is opened and the switch S57 is closed, so that the second filter circuit 42 is connected to the path 44 and the first filter circuit 41 is not connected to the path 44. Then, on the path 44, the second filter circuit 42 functions as a band elimination filter, while the first filter circuit 41 does not function as a band elimination filter.

The opening/closing of the switches S56 and S57 can be controlled based on the channel bandwidth (that is, the modulation bandwidth) of a radio-frequency signal, for example. If the power amplifier 2 is able to amplify radio-frequency signals of multiple frequency bands, the opening/closing of the switches S56 and S57 may be controlled based on the frequency band of a radio-frequency signal, for example. The opening/closing of the switches S56 and S57 may be controlled based on a combination of the channel bandwidth and the frequency band of a radio-frequency signal. The opening/closing of the switches S56 and S57 may be controlled in a different manner.

The switch S56 may be omitted from the tracker circuitry 1. In this case, the first and second filter circuits 41 and 42 are unable to implement the band elimination filter of the mode (iii). Yet, the first and second filter circuits 41 and 42 can still implement two types of band elimination filters of the modes (i) and (ii).

The present inventors have found that, in the power amplification system 7, the linearity of the power amplifier 2 is varied in accordance with the filter circuit connected to the path 44. Based on the findings, in the first embodiment, the DPD circuit 71 switches between DPD mathematical-expression models and/or between their parameter sets in accordance with the above-described modes (i), (ii), and (iii). More specifically, the DPD circuit 71 can calculate predistorted signals by using the following mathematical-expression models and/or their parameter sets in accordance with the above-described modes (i), (ii), and (iii).
(i) The DPD circuit 71 calculates a predistorted signal by using a first parameter set for a first mathematical-expression model.
(ii) The DPD circuit 71 calculates a predistorted signal by using a second parameter set for a second mathematical-expression model.
(iii) The DPD circuit 71 calculates a predistorted signal by using a third parameter set for a third mathematical-expression model.

The relationship between the ON/OFF states of the first and second filter circuits 41 and 42 and the parameter sets used for the corresponding DPD mathematical-expression models can be summarized as in the following Table 1.

TABLE 1

| | First | Second | |
|---|---|---|---|
| | filter | filter | |
| | circuit | circuit | DPD |
| (i) | ON | OFF | First mathematical-expression model |
| | | | First parameter set |
| (ii) | ON | ON | Second mathematical-expression model |
| | | | Second parameter set |
| (iii) | OFF | ON | Third mathematical-expression model |
| | | | Third parameter set |

In the above-described modes, the first mathematical-expression model, second mathematical-expression model, and third mathematical-expression model may be different from each other, or among the three mathematical-expression models, any desired combination of mathematical-expression models may be the same. In one example, any desired two of the first, second, and third mathematical-expression models may be the same and be different from the remaining mathematical-expression model. In another example, all the first, second, and third mathematical-expression models may be the same. In another example, the first, second, and third mathematical-expression models may be all different from each other. As each of the first, second, and third mathematical-expression models, any one of the memoryless polynomial model, MPM, GMP, and another mathematical-expression model may be used.

The first parameter set, second parameter set, and third parameter set are at least partially different from each other. That is, at least one of the first through third parameter sets includes a parameter which is not included in the remaining parameter sets or a parameter whose value is different from that of the remaining parameter sets. Each parameter set does not necessarily include multiple parameters if it includes at least one parameter.

### 1.3.5 Circuit Configuration of Digital Control Circuit 60

The circuit configuration of the digital control circuit 60 will now be explained below. As illustrated in FIG. 3, the digital control circuit 60 includes a first controller 61 and a second controller 62.

The first controller 61 processes a serial data signal (DATA) based on a clock signal (CLK) supplied from the RFIC 3 so as to generate control signals S1 through S4. The serial data signal is a data signal transmitted bit by bit on a single signal line or circuit.

The control signal S1 is a signal for controlling the opening/closing states of the switches S61 through S63, S71, and S72 included in the pre-regulator circuit 10. The control signal S2 is a signal for controlling the opening/closing states of the switches S11 through S14, S21 through S24, S31 through S34, and S41 through S44 included in the switched-capacitor circuit 20. The control signal S3 is a signal for controlling the opening/closing states of the switches S51 through S54 included in the output switch circuit 30 when the APT mode is applied to the power amplifier 2. The control signal S4 is a signal for controlling the opening/closing state of the switch S56 for the first filter circuit 41 and that of the switch S57 for the second filter circuit 42.

For the clock signal to be used by the first controller 61 to process the serial data signal, a signal line different from that for the serial data signal is used. However, this is only an example. For instance, the clock signal may be transmitted on the same signal line for the serial data signal.

In the first embodiment, the single serial data signal is used for controlling the pre-regulator circuit 10, switched-capacitor circuit 20, output switch circuit 30, and switches S56 and S57. However, plural serial data signals may be used.

The second controller 62 processes DCL (Digital Control Logic/Line) signals (DCL1, DCL2) supplied from the RFIC 3 so as to generate a control signal S5. The DCL signals are an example of parallel data signals. The parallel data signals are data signals simultaneously transmitted on plural signal lines or circuits in parallel.

The DCL signals (DCL1, DCL2) are generated by the RFIC 3 based on an envelope signal of a radio-frequency signal when the D-ET mode is applied to the power amplifier 2. Accordingly, the control signal S5 is a signal for controlling the opening/closing states of the switches S51 through S54 included in the output switch circuit 30 when the D-ET mode is applied to the power amplifier 2.

Each of the DCL signals (DCL1, DCL2) is a one-bit signal. The voltages V1 through V4 are each represented by a combination of two one-bit signals. For example, V1, V2, V3, and V4 are represented by “00”, “01”, “10”, and “11”, respectively. For the representation for the voltage level, Gray code may be used.

In the first embodiment, in the D-ET mode, two DCL signals are used for controlling the output switch circuit 30. However, the number of DCL signals is not restricted to two. For example, any desired number (one or three or more) of DCL signals may be used in accordance with the number of voltage levels that the individual switches of the output switch circuit 30 can select. The digital control signal used for controlling the output switch circuit 30 is not limited to a DCL signal.

### 1.4 DPD Method

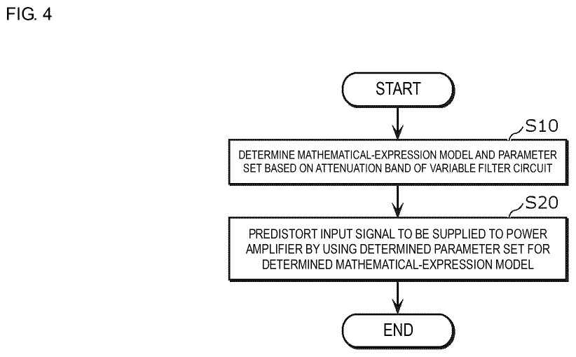

A DPD method according to the first embodiment will be described below with reference to FIG. 4. FIG. 4 is a flowchart illustrating a DPD method according to the first embodiment.

The RFIC 3 first determines a mathematical-expression model for DPD and a parameter set therefor, based on the attenuation band of a variable filter circuit implemented by the first and second filter circuits 41 and 42 and the switches S56 and S57 (S10). In one example, if the attenuation band is formed by the first filter circuit 41 as in the mode (i) in Table 1, the use of the first mathematical-expression model and the first parameter set is determined. In another example, if the attenuation band is formed by the first and second filter circuits 41 and 42 as in the mode (ii) in Table 1, the use of the second mathematical-expression model and the second parameter set is determined. In another example, if the attenuation band is formed by the second filter circuit 42 as in the mode (iii) in Table 1, the use of the third mathematical-expression model and the third parameter set is determined.

More specifically, when the attenuation band of the variable filter circuit is wider than a threshold band, the use of the first parameter set may be determined. When the attenuation band of the variable filter circuit is not wider than the threshold band, the use of the second parameter set, which includes fewer parameters than the first parameter set, may be determined. The threshold band can be determined empirically in advance.

The attenuation band of the variable filter circuit implemented by the first and second filter circuits 41 and 42 and the switches S56 and S57 can be determined by measuring the attenuation characteristics in a range from the output terminal 130 of the output switch circuit 30 to the output terminal of the tracker circuitry 1 which is connected to the power amplifier 2. A network analyzer is used for measuring the attenuation characteristics. To determine the attenuation band, the frequency characteristics of the output voltage at the output terminal of the tracker circuitry 1 which is connected to the power amplifier 2 may be measured with a spectrum analyzer or an oscilloscope.

The RFIC 3 predistorts an input signal to be supplied to the power amplifier 2 by using the determined parameter set for the determined mathematical-expression model (S20). For example, by applying the determined parameter set (such as the polynomial order N, memory depth Q, and DPD coefficient C_{qi}) to the mathematical-expression model (expression (2), for example), the DPD circuit 71 calculates a predistorted digital IQ signal and the DAC 72 converts the calculated predistorted digital IQ signal to a predistorted analog IQ signal. Then, the quadrature modulator 73 performs quadrature modulation and up-conversion on the predistorted analog IQ signal supplied from the DAC 72, thereby generating a predistorted radio-frequency signal RF.

### 1.5 Advantages and Others

As described above, the power amplification system 7 according to the first embodiment includes the power amplifier 2, the output switch circuit 30, the second filter circuit 42, and the DPD circuit 71. The output switch circuit 30 is configured to selectively output at least one of multiple discrete voltages to the power amplifier 2. The second filter circuit 42 is connected in a switchable manner to the path 44, which connects the output switch circuit 30 and the power amplifier 2. The DPD circuit 71 is configured to predistort an input signal to be supplied to the power amplifier 2. (i) When the second filter circuit 42 is not connected to the path 44, the DPD circuit 71 predistorts the input signal to be supplied to the power amplifier 2 by using the first parameter set for the first mathematical-expression model. (ii) When the second filter circuit 42 is connected to the path 44, the DPD circuit 71 predistorts the input signal to be supplied to the power amplifier 2 by using the second parameter set for the second mathematical-expression model. The first parameter set and the second parameter set are at least partially different from each other.

With this configuration, the mathematical-expression models and/or parameter sets can be switched therebetween in accordance with whether the second filter circuit 42 is connected to the path 44, which is used for supplying multiple discrete voltages to the power amplifier 2. It is thus possible to predistort the input signal to be supplied to the power amplifier 2 by using the mathematical-expression model and the parameter set suitable for the power amplifier 2 whose linearity is changed according to whether the second filter circuit 42 is connected to or disconnected from the path 44. This can reduce the nonlinear distortion in the power amplifier 2. For example, if the second filter circuit 42 is selectively connected to the path 44 or is selectively disconnected from the path 44 based on the channel bandwidth of the input signal to be supplied to the power amplifier 2, the input signal to be supplied to the power amplifier 2 may be predistorted by using the mathematical-expression model and the parameter set based on the channel bandwidth. This can further reduce the nonlinear distortion in the power amplifier 2.

Additionally, in one example, the power amplification system 7 according to the first embodiment may also include the first filter circuit 41 which is to connect to the path 44 in a switchable manner. (i) When the first filter circuit 41 is connected to the path 44 and when the second filter circuit 42 is not connected to the path 44, the DPD circuit 71 may predistort the input signal to be supplied to the power amplifier 2 by using the first parameter set for the first mathematical-expression model. (ii) When the first filter circuit 41 is connected to the path 44 and when the second filter circuit 42 is connected to the path 44, the DPD circuit 71 may predistort the input signal to be supplied to the power amplifier 2 by using the second parameter set for the second mathematical-expression model. (iii) When the first filter circuit 41 is not connected to the path 44 and when the second filter circuit 42 is connected to the path 44, the DPD circuit 71 may predistort the input signal to be supplied to the power amplifier 2 by using a third parameter set for a third mathematical-expression model. The first, second, and third parameter sets may be at least partially different from each other.

With this configuration, the mathematical-expression models and/or parameter sets can be switched therebetween in accordance with whether the first filter circuit 41 is connected to the path 44, which is used for supplying multiple discrete voltages to the power amplifier 2, and whether the second filter circuit 42 is connected to the path 44. It is thus possible to predistort the input signal to be supplied to the power amplifier 2 by using the mathematical-expression model and the parameter set suitable for the power amplifier 2. This can reduce the nonlinear distortion in the power amplifier 2.

Additionally, in one example, in the power amplification system 7 according to the first embodiment, the first filter circuit 41 may be connected between the output switch circuit 30 and the power amplifier 2, and the second filter circuit 42 may be connected between the output switch circuit 30 and the power amplifier 2 in parallel with the first filter circuit 41. The power amplification system 7 may also include the switch S56 connected between the output switch circuit 30 and the first filter circuit 41 and the switch S57 connected between the output switch circuit 30 and the second filter circuit 42.

With this configuration, when the first filter circuit 41 and the second filter circuit 42 are connected in series with the path 44, the nonlinear distortion in the power amplifier 2 can be reduced.

In the DPD method according to the first embodiment, a mathematical-expression model for DPD and a parameter set are determined, based on the attenuation band of a variable filter circuit connected between the power amplifier 2 and the output switch circuit 30 that selectively supplies at least one of multiple discrete voltages to the power amplifier (S10). The input signal to be supplied to the power amplifier is predistorted by the application of the determined parameter set to the determined mathematical-expression model (S20).

This can switch between mathematical-expression models and/or between parameter sets in accordance with the attenuation band of a variable filter circuit (the first and second filter circuits 41 and 42 and the switches S56 and S57, for example) connected between the power amplifier 2 and the output switch circuit 30 that supplies multiple discrete voltages to the power amplifier 2. It is thus possible to predistort the input signal to be supplied to the power amplifier 2 by using the mathematical-expression model and the parameter set suitable for the power amplifier 2 whose linearity is varied in accordance with the attenuation band of the variable filter circuit. This can reduce the nonlinear distortion in the power amplifier 2. For example, if the attenuation band of the variable filter circuit is changed based on the channel bandwidth of the input signal to be supplied to the power amplifier 2, the input signal to be supplied to the power amplifier 2 may be predistorted with the use of the mathematical-expression model and the parameter set based on the channel bandwidth. This can further reduce the nonlinear distortion in the power amplifier 2.

Additionally, for example, in the DPD method according to the first embodiment, in determining the mathematical-expression model and the parameter set (S10), when the attenuation band of the variable filter circuit is wider than a threshold band, the use of the first parameter set may be determined. When the attenuation band of the variable filter circuit is not wider than the threshold band, the use of the second parameter set, which includes fewer parameters than the first parameter set, may be determined.

With this configuration, when the attenuation band is narrow and the channel bandwidth of a radio-frequency signal RF is also narrow, fewer parameters are used, thereby making it possible to reduce the calculation load for DPD and accordingly lower the power consumption. Conversely, when the attenuation band is wide and the channel bandwidth of a radio-frequency signal RF is also wide, more parameters are used, thereby making it possible to reduce the nonlinear distortion in the power amplifier 2.

The second filter circuit 42 is connected in a switchable manner to the path 44, which is used for selectively supplying at least one of multiple discrete voltages to the power amplifier 2. (i) When the second filter circuit 42 is not connected to the path 44, a first input signal to be supplied to the power amplifier 2 is predistorted using the first parameter set for the first mathematical-expression model. (ii) When the second filter circuit 42 is connected to the path 44, the first input signal is predistorted using the second parameter set for the second mathematical-expression model. The first parameter set and the second parameter set are at least partially different from each other.

With this configuration, the mathematical-expression models and/or parameter sets can be switched therebetween in accordance with whether the second filter circuit 42 is connected to the path 44 for supplying multiple discrete voltages to the power amplifier 2. It is thus possible to predistort the input signal to be supplied to the power amplifier 2 by using the mathematical-expression model and the parameter set suitable for the power amplifier 2 whose linearity is changed according to whether the second filter circuit 42 is connected to or disconnected from the path 44. This can reduce the nonlinear distortion in the power amplifier 2. For example, if the second filter circuit 42 is connected to or disconnected from the path 44 based on the channel bandwidth of the input signal to be supplied to the power amplifier 2, the input signal to the power amplifier 2 may be predistorted using the mathematical-expression model and the parameter set based on the channel bandwidth. This can further reduce the nonlinear distortion in the power amplifier 2.

Additionally, in one example, (i) when the first filter circuit 41, which is connected to the path 44 in a switchable manner, is connected to the path 44 and when the second filter circuit 42 is not connected to the path 44, the digital predistortion circuit 71 in the first embodiment may predistort the first input signal to be supplied to the power amplifier 2 by using the first parameter set for the first mathematical-expression model. (ii) When the first filter circuit 41 is connected to the path 44 and when the second filter circuit 42 is connected to the path 44, the digital predistortion circuit 71 may predistort the first input signal to be supplied to the power amplifier 2 by using the second parameter set for the second mathematical-expression model. (iii) When the first filter circuit 41 is not connected to the path 44 and when the second filter circuit 42 is connected to the path 44, the digital predistortion circuit 71 may predistort the first input signal to be supplied to the power amplifier 2 by using the third parameter set for the third mathematical-expression model. The first, second, and third parameter sets may be at least partially different from each other.

With this configuration, the mathematical-expression models and/or parameter sets can be switched therebetween in accordance with whether the first filter circuit 41 is connected to the path 44, which is used for supplying multiple discrete voltages to the power amplifier 2, and whether the second filter circuit 42 is connected to the path 44. It is thus possible to predistort the input signal to be supplied to the power amplifier 2 by using the mathematical-expression model and the parameter set suitable for the power amplifier 2. This can reduce the nonlinear distortion in the power amplifier 2.

### First Modified Example of First Exemplary Embodiment

A first modified example of the first embodiment will now be described below. The first modified example is different from the first embodiment mainly in the circuit configurations of the first and second filter circuits. Hereinafter, the first modified example will be discussed below with reference to the drawing mainly by referring to the points different from the first embodiment.

The circuit configuration of the communication apparatus 6 according to the first modified example is similar to that of the first embodiment, except for part of the tracker circuitry 1, and an explanation and illustration thereof will thus be omitted unless necessary.

### 2.1 Circuit Configuration of Tracker Circuitry 1

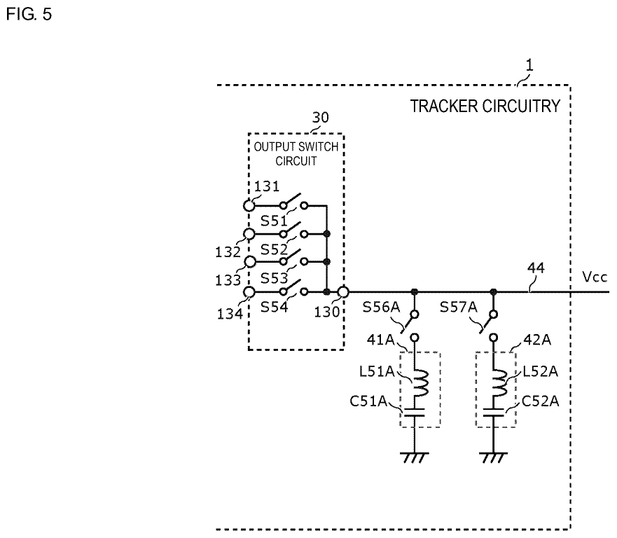

The circuit configuration of the tracker circuitry 1 according to the first modified example will be explained below with reference to FIG. 5. FIG. 5 is a partial circuit diagram of the tracker circuitry 1 according to the first modified example.

The circuit configuration shown in FIG. 5 is only an example. The tracker circuitry 1 can be implemented by using any of a variety of circuit implementations and circuit technologies. Hence, the following explanation of the tracker circuitry 1 is not to be interpreted in a limited manner.

Instead of the first filter circuit 41, the second filter circuit 42, and the switches S56 and S57 in the first embodiment, the tracker circuitry 1 according to the first modified example includes a first filter circuit 41A, a second filter circuit 42A, and switches S56A and S57A.

The first filter circuit 41A is connected to the path 44 in a switchable manner. More specifically, the first filter circuit 41A is connected between the path 44 and a ground via the switch S56A. The first filter circuit 41A includes a series circuit (LC series circuit) of an inductor L51A and a capacitor C51A. One end of the series circuit of the inductor L51A and the capacitor C51A is connected to the path 44 via the switch S56A, and the other end of the series circuit is connected to a ground. The first filter circuit 41A is not limited to an LC series circuit.

The second filter circuit 42A is connected in a switchable manner to the path 44, which connects the output switch circuit 30 and the power amplifier 2. More specifically, the second filter circuit 42A is connected between the path 44 and a ground via the switch S57A. The second filter circuit 42A includes a series circuit of an inductor L52A and a capacitor C52A. One end of the series circuit of the inductor L52A and the capacitor C52A is connected to the path 44 via the switch S57A, and the other end of the series circuit is connected to a ground. The second filter circuit 42A is not limited to an LC series circuit.

The first and second filter circuits 41A and 42A may also be called a pulse shaping network or a transition shaping filter. One of the first filter circuit 41A and the second filter circuit 42A may be omitted from the tracker circuitry 1. To put it another way, only one of the first and second filter circuits 41A and 42A may be included in the tracker circuitry 1

The switch S56A is an example of the first switch and is an ON/OFF switch for the first filter circuit 41A. The switch S56A is connected between the path 44 and the first filter circuit 41A.

The switch S57A is an example of the second switch and is an ON/OFF switch for the second filter circuit 42A. The switch S57A is connected between the path 44 and the second filter circuit 42A.

The first filter circuit 41A connected in this manner is switched between ON and OFF by the switch S56A, while the second filter circuit 42A connected in this manner is switched between ON and OFF by the switch S57A. On the path 44, the first and second filter circuits 41A and 42A can thus change the attenuation band of a band elimination filter used for removing noise from multiple discrete voltages. That is, the first and second filter circuits 41A and 42A function as a variable filter circuit that can switch between multiple attenuation bands.

Under the opening/closing control of the switches S56A and S57A, the first and second filter circuits 41A and 42A of the first modified example can implement three types of band elimination filters indicated by the following modes (i), (ii), and (iii).
(i) The switch S56A is closed and the switch S57A is opened, so that the first filter circuit 41A is connected to the path 44 and the second filter circuit 42A is not connected to the path 44. Then, on the path 44, the first filter circuit 41A functions as a band elimination filter, while the second filter circuit 42A does not function as a band elimination filter.
(ii) The switch S56A is closed and the switch S57A is closed, so that the first filter circuit 41A and the second filter circuit 42A are both connected to the path 44. Then, on the path 44, the first and second filter circuits 41A and 42A serve as a band elimination filter.
(iii) The switch S56A is opened and the switch S57A is closed, so that the second filter circuit 42A is connected to the path 44 and the first filter circuit 41A is not connected to the path 44. Then, on the path 44, the second filter circuit 42A functions as a band elimination filter, while the first filter circuit 41A does not function as a band elimination filter.

As in the switches S56 and S57 of the first embodiment, the opening/closing of the switches S56A and S57A can be controlled based on the channel bandwidth and/or the frequency band of a radio-frequency signal RF, for example.

As in the first embodiment, the DPD circuit 71 of the first modified example can switch between the DPD mathematical-expression models and/or between their parameter sets in accordance with the above-described modes (i), (ii), and (iii). In the first modified example, the relationship between the ON/OFF states of the first and second filter circuits 41A and 42A and the parameter sets used for the corresponding DPD mathematical-expression models can be summarized as in the following Table 2.

TABLE 2

| | First | Second | |
|---|---|---|---|
| | filter | filter | |
| | circuit | circuit | DPD |
| (i) | ON | OFF | First mathematical-expression model |
| | | | First parameter set |
| (ii) | ON | ON | Second mathematical-expression model |
| | | | Second parameter set |
| (iii) | OFF | ON | Third mathematical-expression model |
| | | | Third parameter set |

In Table 2, the first mathematical-expression model, second mathematical-expression model, and third mathematical-expression model may be different from each other, or among the three mathematical-expression models, any desired combination of mathematical-expression models may be the same. The first, second, and third parameter sets are at least partially different from each other.

The switch S56A may be omitted from the tracker circuitry 1. In this case, the first and second filter circuits 41A and 42A are unable to implement the band elimination filter of the mode (iii). Yet, the first and second filter circuits 41A and 42A can still implement two types of band elimination filters of the modes (i) and (ii).

In the above-described modes (i), (ii), and (iii), at least one of the switches S56A and S57A is closed. However, both of the switches S56A and S57A may be opened. In this case, neither of the first filter circuit 41A nor the second filter circuit 42A functions as a band elimination filter on the path 44. That is, there may be a mode in which the variable filter circuit constituted by the first and second filter circuits 41A and 42A does not have an effective attenuation band.

### 2.2 Advantages and Others

As described above, in the power amplification system 7 according to the first modified example, the first filter circuit 41A may be connected between the path 44 and a ground, while the second filter circuit 42A may be connected between the path 44 and a ground in parallel with the first filter circuit 41A. The power amplification system 7 may also include the switch S56A connected between the path 44 and the first filter circuit 41A and the switch S57A connected between the path 44 and the second filter circuit 42A.

With this configuration, when the first filter circuit 41A and the second filter circuit 42A are shunt-connected to the path 44, too, the nonlinear distortion in the power amplifier 2 can be reduced.

### Second Modified Example of First Exemplary Embodiment

A second modified example of the first embodiment will now be described below. The second modified example is different from the first embodiment and the first modified example thereof mainly in the circuit configurations of the first and second filter circuits. Hereinafter, the second modified example will be discussed below with reference to the drawing mainly by referring to the points different from the first embodiment and the first modified example thereof.

The circuit configuration of the communication apparatus 6 according to the second modified example is similar to that of the first embodiment, except for part of the tracker circuitry 1, and an explanation and illustration thereof will thus be omitted unless necessary.

### 3.1 Circuit Configuration of Tracker Circuitry 1

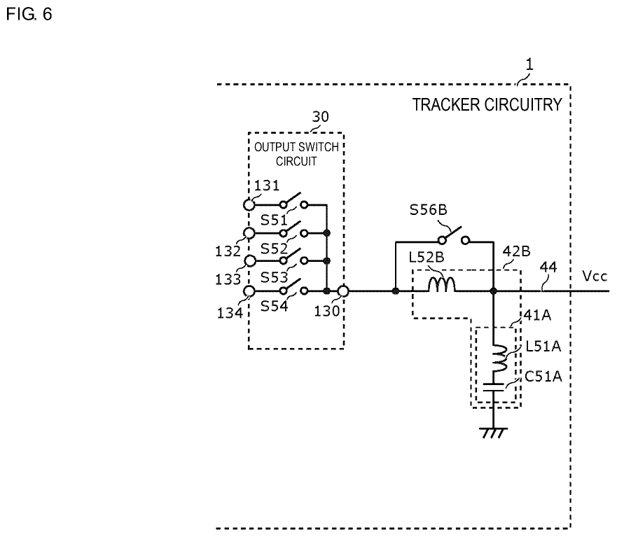

The circuit configuration of the tracker circuitry 1 according to the second modified example will be explained below with reference to FIG. 6. FIG. 6 is a partial circuit diagram of the tracker circuitry 1 according to the second modified example.

The circuit configuration shown in FIG. 6 is only an example. The tracker circuitry 1 can be implemented by using any of a variety of circuit implementations and circuit technologies. Hence, the following explanation of the tracker circuitry 1 is not to be interpreted in a limited manner.

Instead of the first filter circuit 41, the second filter circuit 42, and the switches S56 and S57 in the first embodiment, the tracker circuitry 1 according to the second modified example includes a first filter circuit 41A, a second filter circuit 42B, and a switch S56B.

The first filter circuit 41A is connected to the path 44 in a switchable manner. More specifically, the first filter circuit 41A is connected between the path 44 and a ground via the switch S56B. One end of a series circuit of an inductor L51A and a capacitor C51A of the first filter circuit 41A is connected to a portion of the path 44 between an inductor L52B and the power amplifier 2, and the other end of the series circuit of the inductor L51A and the capacitor C51A is connected to a ground.

The second filter circuit 42B is connected to the path 44 in a switchable manner. More specifically, the second filter circuit 42B includes the inductor L52B and the series circuit of the inductor L51A and the capacitor C51A. One end of the inductor L52B is connected to the output switch circuit 30, and the other end of the inductor L52B is connected to the power amplifier 2. The second filter circuit 42B may also be called a pulse shaping network or a transition shaping filter.

The switch S56B is used for switching the ON/OFF state of the first filter circuit 41A and that of the second filter circuit 42B. The switch S56B is connected in parallel with the inductor L52B. That is, one end of the switch S56B is connected to one end of the inductor L52B, and the other end of the switch S56B is connected to the other end of the inductor L52B.

The first filter circuit 41A and the second filter circuit 42B connected in this manner are each switched between ON and OFF by the switch S56B. On the path 44, the first and second filter circuits 41A and 42B can thus change the attenuation band of a band elimination filter used for removing noise from multiple discrete voltages. That is, the first and second filter circuits 41A and 42B function as a variable filter circuit that can switch between multiple attenuation bands.

Under the opening/closing control of the switch S56B, the first and second filter circuits 41A and 42B of the second modified example can implement two types of band elimination filters indicated by the following modes (i) and (ii).
(i) The switch S56B is closed, so that the first filter circuit 41A is connected to the path 44. Then, on the path 44, the first filter circuit 41A functions as a band elimination filter, while the second filter circuit 42B does not function as a band elimination filter.
(ii) The switch S56B is opened, so that the second filter circuit 42B is connected to the path 44. Then, on the path 44, the first filter circuit 41A does not function as a band elimination filter, while the second filter circuit 42B functions as a band elimination filter.

As in the switches S56 and S57 of the first embodiment, the opening/closing of the switch S56B can be controlled based on the channel bandwidth and/or the frequency band of a radio-frequency signal RF, for example.

The DPD circuit 71 of the second modified example can switch between the DPD mathematical-expression models and/or between their parameter sets in accordance with the above-described modes (i) and (ii). In the second modified example, the relationship between the ON/OFF states of the first and second filter circuits 41A and 42B and the parameter sets used for the corresponding DPD mathematical-expression models can be summarized as in the following Table 3.

TABLE 3

| | First | Second | |
|---|---|---|---|
| | filter | filter | |
| | circuit | circuit | DPD |
| (i) | ON | OFF | First mathematical-expression model |
| | | | First parameter set |
| (ii) | OFF | ON | Second mathematical-expression model |
| | | | Second parameter set |

In Table 3, the first mathematical-expression model and the second mathematical-expression model may be different from each other or may be the same. The first parameter set and the second parameter set are at least partially different from each other.

### 3.2 Advantages and Others

As described above, in the power amplification system 7 according to the second modified example, the first filter circuit 41A may include a series circuit of the inductor L51A and the capacitor C51A connected between the path 44 and a ground. The second filter circuit 42B may include the series circuit of the inductor L51A and the capacitor C51A and the inductor L52B which is connected between the output switch circuit 30 and the power amplifier 2. The power amplification system 7 may also include the switch S56B connected in parallel with the inductor L52B.

With this configuration, when the first filter circuit 41A is shunt-connected to the path 44 and when the second filter circuit 42B is connected in series with the path 44, too, the nonlinear distortion in the power amplifier 2 can be reduced.

### Third Modified Example of First Exemplary Embodiment

A third modified example of the first embodiment will now be described below. The third modified example is different from the first embodiment mainly in that the second filter circuit is not included in the tracker circuitry. Hereinafter, the third modified example will be discussed below with reference to the drawing mainly by referring to the points different from the first embodiment.

The circuit configuration of the communication apparatus 6 according to the third modified example is similar to that of the first embodiment, except for part of the tracker circuitry 1, and an explanation and illustration thereof will thus be omitted unless necessary.

### 4.1 Circuit Configuration of Tracker Circuitry 1

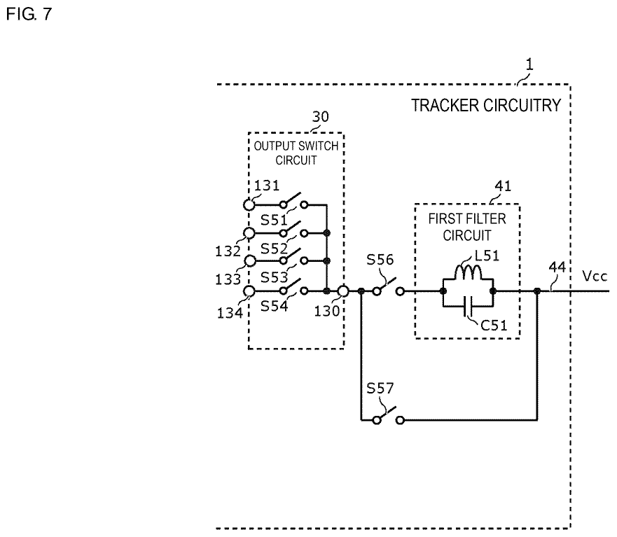

The circuit configuration of the tracker circuitry 1 according to the third modified example will be explained below with reference to FIG. 7. FIG. 7 is a partial circuit diagram of the tracker circuitry 1 according to the third modified example.

The circuit configuration shown in FIG. 7 is only an example. The tracker circuitry 1 can be implemented by using any of a variety of circuit implementations and circuit technologies. Hence, the following explanation of the tracker circuitry 1 is not to be interpreted in a limited manner.

The tracker circuitry 1 of the third modified example does not include the second filter circuit 42 of the first embodiment. The switch S57 thus functions as a switch that selectively connects the first filter circuit 41 to a bypass path or disconnects the first filter circuit 41 from the bypass path. Specifically, the switch S57 is connected between the output switch circuit 30 and the power amplifier 2 without having the first filter circuit 41 interposed therebetween. More specifically, one end of the switch S57 is connected to one end of the first filter circuit 41 via the switch S56, and the other end of the switch S57 is connected to the other end of the first filter circuit 41.

In FIG. 7, the first filter circuit 41 is switched between ON and OFF by the switches S56 and S57. On the path 44, the first filter circuit 41 can thus change the attenuation band of a band elimination filter used for removing noise from multiple discrete voltages. More specifically, the switches S56 and S57 can determine whether a band elimination filter is provided on the path 44. That is, the first filter circuit 41 functions as a variable filter circuit that can determine whether an attenuation band is provided.

Under the opening/closing control of the switches S56 and S57, the first filter circuit 41 of the third modified example can implement the following two modes (i) and (ii).
(i) The switch S56 is opened and the switch S57 is closed, so that the first filter circuit 41 is not connected to the path 44. Then, on the path 44, the first filter circuit 41 does not function as a band elimination filter.
(ii) The switch S56 is closed and the switch S57 is opened, so that the first filter circuit 41 is connected to the path 44. Then, on the path 44, the first filter circuit 41 functions as a band elimination filter.

As in the first embodiment, the opening/closing of the switches S56 and S57 can be controlled based on the channel bandwidth and/or the frequency band of a radio-frequency signal RF, for example.

As in the first embodiment, the DPD circuit 71 of the third modified example can switch between the DPD mathematical-expression models and/or between their parameter sets in accordance with the above-described modes (i) and (ii). In the third modified example, the relationship between the ON/OFF state of the first filter circuit 41 and the parameter sets used for the corresponding DPD mathematical-expression models can be summarized as in the following Table 4.

TABLE 4

| | First filter circuit | DPD |
|---|---|---|
| (i) | OFF | First mathematical-expression model |
| | | First parameter set |
| (ii) | ON | Second mathematical-expression model |
| | | Second parameter set |

In Table 4, the first mathematical-expression model and the second mathematical-expression model may be different from each other or may be the same. The first parameter set and the second parameter set are at least partially different from each other.

### 4.2 Advantages and Others

As described above, in the power amplification system 7 according to the third modified example, the first filter circuit 41 may be connected between the output switch circuit 30 and the power amplifier 2. The power amplification system 7 may also include the switch S56 connected between the output switch circuit 30 and the first filter circuit 41 and the switch S57 connected between the output switch circuit 30 and the power amplifier 2 without having the first filter circuit 41 interposed therebetween.

With this configuration, it is possible to switch between mathematical-expression models and/or between parameter sets in accordance with whether or not the first filter circuit 41 is connected in series with the path 44. The nonlinear distortion in the power amplifier 2 can thus be reduced.

### Second Exemplary Embodiment

A second exemplary embodiment will now be described below. The second embodiment is different from the above-described first embodiment mainly in that a power supply voltage is supplied to two power amplifiers from the tracker circuitry. Hereinafter, the second embodiment will be discussed below with reference to the drawings mainly by referring to the points different from the first embodiment.

### 5.1 Circuit Configuration of Communication Apparatus 6A

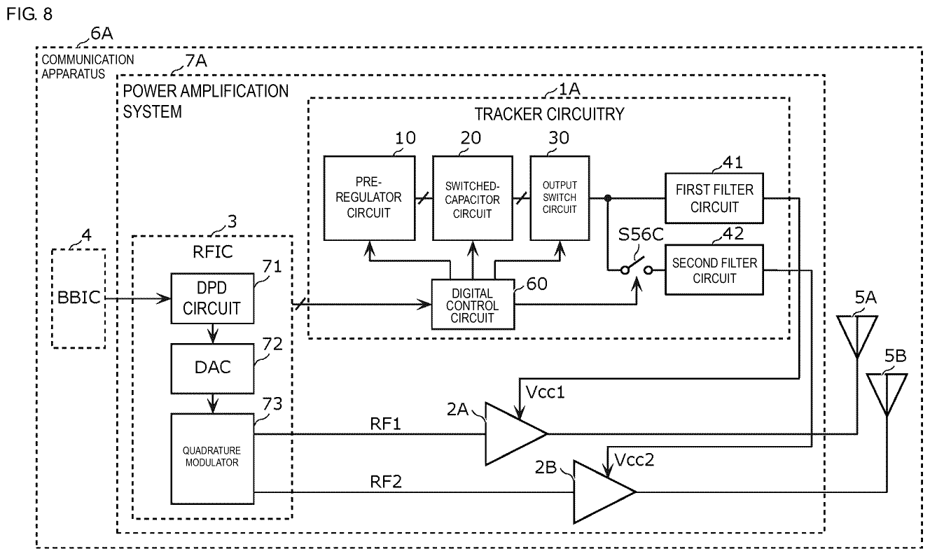

The circuit configuration of a communication apparatus 6A according to the second embodiment will first be described below with reference to FIG. 8. FIG. 8 is a circuit diagram of the communication apparatus 6A according to the second embodiment.

The circuit configuration shown in FIG. 8 is only an example. The communication apparatus 6A can be implemented by using any of a variety of circuit implementations and circuit technologies. Hence, the following explanation of the communication apparatus 6A is not to be interpreted in a limited manner.

As illustrated in FIG. 8, the communication apparatus 6A includes tracker circuitry 1A, first and second power amplifiers 2A and 2B, an RFIC 3, a BBIC 4, and antennas 5A and 5B. A power amplification system 7A includes the tracker circuitry 1A, the first and second power amplifiers 2A and 2B, and the RFIC 3.

Based on a tracking mode, the tracker circuitry 1A is able to supply multiple discrete voltages to the first and second power amplifiers 2A and 2B as power supply voltages Vcc1 and Vcc2, respectively. The power supply voltages Vccl and Vcc2 are supplied to the first and second power amplifiers 2A and 2B mutually exclusively. In the second embodiment, as the tracking mode, the D-ET mode and the APT mode are used. However, the tracking mode to be used is not limited to these modes.

The first power amplifier 2A is connected between the RFIC 3 and the antenna 5A. The first power amplifier 2A is also connected to the tracker circuitry 1A. The first power amplifier 2A is able to amplify a radio-frequency signal RF1 (an example of the first input signal) supplied from the RFIC 3 by using the power supply voltage Vccl supplied from the tracker circuitry 1A.

The second power amplifier 2B is connected between the RFIC 3 and the antenna 5B. The second power amplifier 2B is also connected to the tracker circuitry 1A. The second power amplifier 2B is able to amplify a radio-frequency signal RF2 (an example of a second input signal) supplied from the RFIC 3 by using the power supply voltage Vcc2 supplied from the tracker circuitry 1A.

The RFIC 3 is an example of a signal processing circuit that processes a radio-frequency signal. The RFIC 3 can receive a digital IQ signal from the BBIC 4 and supply the radio-frequency signal RF1 to the first power amplifier 2A. The RFIC 3 can also receive a digital IQ signal from the BBIC 4 and supply the radio-frequency signal RF2 to the second power amplifier 2B. The internal configuration of the RFIC 3 is similar to that of the first embodiment and an explanation thereof will thus be omitted.

The BBIC 4 is a baseband signal processing circuit that performs signal processing by using a frequency band lower than the radio-frequency signals RF1 and RF2. The BBIC 4 performs digital modulation on a bit sequence which represents an image signal for displaying an image and/or an audio signal for performing communication via a speaker, thereby generating a digital IQ signal. The generated IQ signal is supplied to the RFIC 3. The BBIC 4 may be omitted from the communication apparatus 6A.

The antenna 5A sends the radio-frequency signal RFI amplified by the first power amplifier 2A to the outside of the communication apparatus 6A. The antenna 5B sends the radio-frequency signal RF2 amplified by the second power amplifier 2B to the outside of the communication apparatus 6A. The antenna 5A and/or the antenna 5B may be omitted from the communication apparatus 6A.

### 5.2 Circuit Configuration of Tracker Circuitry 1A

The circuit configuration of the tracker circuitry 1A will be described below with reference to FIG. 8. The tracker circuitry 1A includes a pre-regulator circuit 10, a switched-capacitor circuit 20, an output switch circuit 30, first and second filter circuits 41 and 42, a switch S56C, and a digital control circuit 60. The pre-regulator circuit 10, the switched-capacitor circuit 20, and the digital control circuit 60 are similar to the counterparts of the first embodiment and an explanation thereof will thus be omitted.

The output switch circuit 30 can selectively output at least one of the multiple discrete voltages generated by the switched-capacitor circuit 20 to the first and second power amplifiers 2A and 2B mutually exclusively.

The first and second filter circuits 41 and 42 can respectively attenuate noise from multiple discrete voltages to be supplied to the first and second power amplifiers 2A and 2B.

The switch S56C is an example of the first switch and is an ON/OFF switch for the second filter circuit 42. The switch S56C is connected between the output switch circuit 30 and the second filter circuit 42.

### 5.2.1 Circuit Configuration of First Filter Circuit 41 and Second Filter Circuit 42

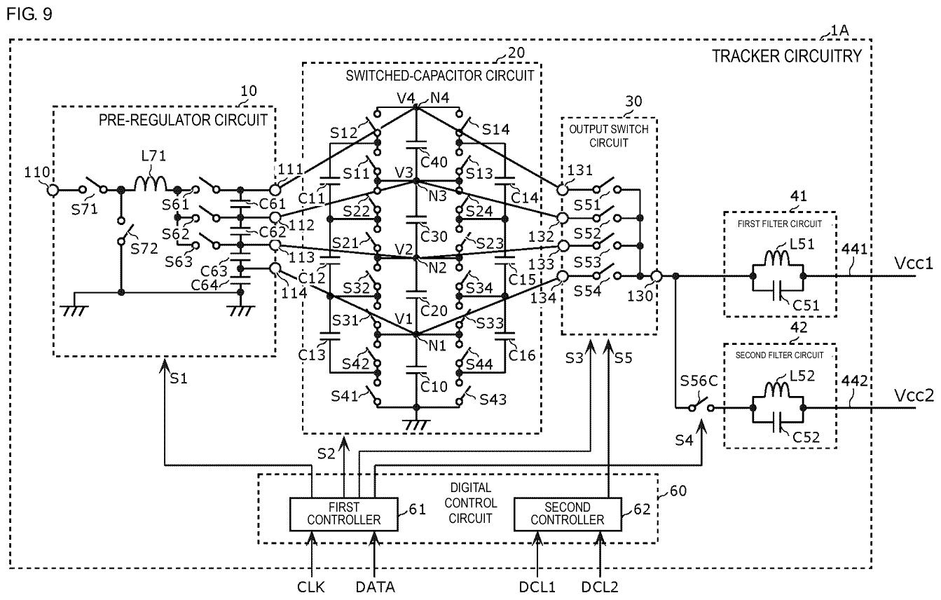

The circuit configurations of the first and second filter circuits 41 and 42 included in the tracker circuitry 1A will be explained below with reference to FIG. 9. FIG. 9 is a circuit diagram of the tracker circuitry 1A according to the second embodiment.

The circuit configuration shown in FIG. 9 is only an example. The tracker circuitry 1A can be implemented by using any of a variety of circuit implementations and circuit technologies. Hence, the following explanation of the tracker circuitry 1A is not to be interpreted in a limited manner.

The pre-regulator circuit 10, switched-capacitor circuit 20, output switch circuit 30, and digital control circuit 60 are similar to the counterparts of the first embodiment and an explanation thereof will thus be omitted.

The first filter circuit 41 is connected to a first path 441 that connects the output switch circuit 30 and the first power amplifier 2A and to a second path 442 that connects the output switch circuit 30 and the second power amplifier 2B. More specifically, the first filter circuit 41 is connected between the output switch circuit 30 and the first power amplifier 2A. One end of a parallel circuit of an inductor L51 and a capacitor C51 of the first filter circuit 41 is connected to the output switch circuit 30. The other end of the parallel circuit of the inductor L51 and the capacitor C51 is connected to the first power amplifier 2A.

The second filter circuit 42 is connected to each of the first and second paths 441 and 442 in a switchable manner. More specifically, the second filter circuit 42 is connected between the output switch circuit 30 and the second power amplifier 2B via the switch S56C. One end of a parallel circuit of an inductor L52 and a capacitor C52 of the second filter circuit 42 is connected to the output switch circuit 30 via the switch S56C. The other end of the parallel circuit of the inductor L52 and the capacitor C52 is connected to the second power amplifier 2B.

The second filter circuit 42 connected in this manner is switched between ON and OFF by the switch S56C. On the first and second paths 441 and 442, the second filter circuit 42 can thus change the attenuation band of a band elimination filter used for removing noise from multiple discrete voltages. That is, the first and second filter circuits 41 and 42 function as a variable filter circuit that can switch between multiple attenuation bands.

Under the opening/closing control of the switch S56C, the first and second filter circuits 41 and 42 of the second embodiment can implement three types of band elimination filters indicated by the following modes (i), (ii), and (iii).
(i) When the first power amplifier 2A amplifies the radio-frequency signal RF1, the switch S56C is opened so that the first filter circuit 41 is connected to the first path 441 and the second filter circuit 42 is not connected to the first path 441. Then, on the first path 441, the first filter circuit 41 functions as a band elimination filter, while the second filter circuit 42 does not function as a band elimination filter.
(ii) When the first power amplifier 2A amplifies the radio-frequency signal RF1, the switch S56C is closed so that the first and second filter circuits 41 and 42 are connected to the first path 441. Then, on the first path 441, the first and second filter circuits 41 and 42 function as a band elimination filter.
(iii) When the second power amplifier 2B amplifies the radio-frequency signal RF2, the switch S56C is closed so that the first and second filter circuits 41 and 42 are connected to the second path 442. Then, on the second path 442, the first and second filter circuits 41 and 42 function as a band elimination filter.

The opening/closing of the switch S56C can be controlled based on the power amplifier used for amplifying a radio-frequency signal, the channel bandwidth of the radio-frequency signal, the frequency band of the radio-frequency signal, or a desired combination thereof, for example.

The DPD circuit 71 according to the second embodiment can switch between the DPD mathematical-expression models and/or between their parameter sets in accordance with the above-described modes (i), (ii), and (iii). In the second embodiment, the relationships between the ON/OFF states of the first and second power amplifiers 2A and 2B, the ON/OFF states of the first and second filter circuits 41 and 42, and the parameter sets used for the corresponding DPD mathematical-expression models can be summarized as in the following Table 5.

TABLE 5

| | First | Second | First | Second | |
|---|---|---|---|---|---|
| | power | power | filter | filter | |
| | amplifier | amplifier | circuit | circuit | DPD |
| (i) | ON | OFF | ON | OFF | First mathematical- |
| | | | | | expression model |
| | | | | | First parameter set |
| (ii) | ON | OFF | ON | ON | Second mathematical- |
| | | | | | expression model |
| | | | | | Second parameter set |
| (iii) | OFF | ON | ON | ON | Third mathematical- |
| | | | | | expression model |
| | | | | | Third parameter set |

In Table 5, the first mathematical-expression model, second mathematical-expression model, and third mathematical-expression model may be different from each other, or among the three mathematical-expression models, any desired combination of mathematical-expression models may be the same. The first, second, and third parameter sets are at least partially different from each other.

The tracker circuitry 1A may also include an additional switch connected between the output switch circuit 30 and the first filter circuit 41. In this case, the first and second filter circuits 41 and 42 can implement band elimination filters of the following mode (iv) in addition to the modes (i), (ii), and (iii).
(iv) When the second power amplifier 2B amplifies the radio-frequency signal RF2, the additional switch is opened and the switch S56C is closed so that the first filter circuit 41 is not connected to the second path 442 and the second filter circuit 42 is connected to the second path 442. Then, on the second path 442, the first filter circuit 41 does not function as a band elimination filter, while the second filter circuit 42 functions as a band elimination filter.

### 5.3 Advantages and Others

As described above, the power amplification system 7A according to the second embodiment includes the first and second power amplifiers 2A and 2B, the output switch circuit 30, the first and second filter circuits 41 and 42, and the DPD circuit 71. The output switch circuit 30 is configured to selectively output at least one of multiple discrete voltages to the first and second power amplifiers 2A and 2B. The first filter circuit 41 is connected to the first path 441, which connects the output switch circuit 30 and the first power amplifier 2A, and is also connected to the second path 442, which connects the output switch circuit 30 and the second power amplifier 2B. The second filter circuit 42 is connected to the first path 441 in a switchable manner and is also connected to the second path 442 in a switchable manner. The DPD circuit 71 is configured to predistort a first input signal to be supplied to the first power amplifier 2A and a second input signal to be supplied to the second power amplifier 2B. In a case in which the first power amplifier 2A amplifies the first input signal: (i) when the second filter circuit 42 is not connected to the first path 441, the DPD circuit 71 predistorts the first input signal by using a first parameter set for a first mathematical-expression model; and (ii) when the second filter circuit 42 is connected to the first path 441, the DPD circuit 71 predistorts the first input signal by using a second parameter set for a second mathematical-expression model. In a case in which the second power amplifier 2B amplifies the second input signal, (iii) when the second filter circuit 42 is connected to the second path 442, the DPD circuit 71 predistorts the second input signal by using a third parameter set for a third mathematical-expression model. The first, second, and third parameter sets are at least partially different from each other.

With this configuration, the mathematical-expression models and/or parameter sets can be switched therebetween in accordance with whether the second filter circuit 42 is connected to the first path 441, which is used for supplying multiple discrete voltages to the first power amplifier 2A. It is thus possible to predistort the input signal to be supplied to the first power amplifier 2A by using the mathematical-expression model and the parameter set suitable for the first power amplifier 2A whose linearity is changed according to whether the second filter circuit 42 is connected to or disconnected from the first path 441. This can reduce the nonlinear distortion in the first power amplifier 2A. Additionally, according to the second embodiment, the mathematical-expression models and/or parameter sets can be switched therebetween in accordance with whether the first power amplifier 2A or the second power amplifier 2B is used. It is thus possible to predistort the input signal to be supplied to the first power amplifier 2A by using the mathematical-expression model and the parameter set suitable for the first power amplifier 2A and also to predistort the input signal to be supplied to the second power amplifier 2B by using the mathematical-expression model and the parameter set suitable for the second power amplifier 2B. This can reduce the nonlinear distortion in the first and second power amplifiers 2A and 2B.

Additionally, in one example, in the power amplification system 7A according to the second embodiment, the first filter circuit 41 may be connected between the output switch circuit 30 and the first power amplifier 2A, and the second filter circuit 42 may be connected between the output switch circuit 30 and the second power amplifier 2B. The power amplification system may also include the switch S56C connected between the output switch circuit 30 and the second filter circuit 42.

With this configuration, when the first filter circuit 41 is connected in series with the first path 441 and when the second filter circuit 42 is connected in series with the second path 442, the nonlinear distortion in the first and second power amplifiers 2A and 2B can be reduced.

Additionally, in a case in which the first power amplifier 2A amplifies the first input signal: (i) when the second filter circuit 42 is not connected to the first path 441, the DPD circuit 71 of the second embodiment predistorts the first input signal to be supplied to the first power amplifier 2A by using the first parameter set for the first mathematical- expression model; and (ii) when the second filter circuit 42 is connected to the first path 441, the DPD circuit 71 predistorts the first input signal by using the second parameter set for the second mathematical-expression model. In a case in which the second power amplifier 2B amplifies the second input signal, (iii) when the second filter circuit 42 is connected to the second path 442, the DPD circuit 71 predistorts the second input signal by using the third parameter set for the third mathematical-expression model. The first, second, and third parameter sets are at least partially different from each other.

With this configuration, the mathematical-expression models and/or parameter sets can be switched therebetween in accordance with whether the second filter circuit 42 is connected to the first path 441 for supplying multiple discrete voltages to the first power amplifier 2A. It is thus possible to predistort the input signal to be supplied to the first power amplifier 2A by using the mathematical-expression model and the parameter set suitable for the first power amplifier 2A whose linearity is changed according to whether the second filter circuit 42 is connected to or disconnected from the first path 441. This can reduce the nonlinear distortion in the first power amplifier 2A. Additionally, according to the second embodiment, the mathematical-expression models and/or parameter sets can be switched therebetween in accordance with whether the first power amplifier 2A or the second power amplifier 2B is used. It is thus possible to predistort the input signal to be supplied to the first power amplifier 2A by using the mathematical-expression model and the parameter set suitable for the first power amplifier 2A and to predistort the input signal to be supplied to the second power amplifier 2B by using the mathematical-expression model and the parameter set suitable for the second power amplifier 2B. This can reduce the nonlinear distortion in the first and second power amplifiers 2A and 2B.

### First Modified Example of Second Exemplary Embodiment

A first modified example of the second embodiment will now be described below. The first modified example is different from the second embodiment mainly in the circuit configurations of the first and second filter circuits. Hereinafter, the first modified example will be discussed below with reference to the drawing mainly by referring to the points different from the second embodiment and the first modified example of the first embodiment.

The circuit configuration of the communication apparatus 6A according to the first modified example is similar to that of the second embodiment, except for part of the tracker circuitry 1A, and an explanation and illustration thereof will thus be omitted unless necessary.

### 6.1 Circuit Configuration of Tracker Circuitry 1A

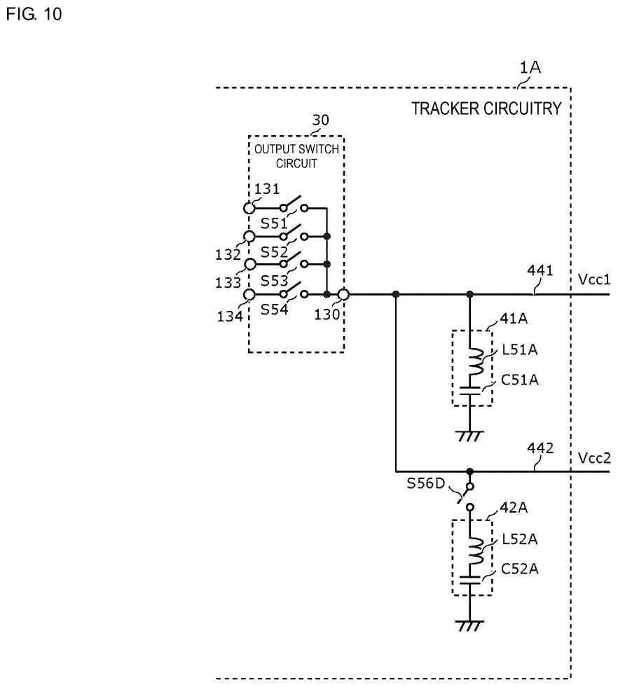

The circuit configuration of the tracker circuitry 1A according to the first modified example will be described below with reference to FIG. 10. FIG. 10 is a partial circuit diagram of the tracker circuitry 1A according to the first modified example.

The circuit configuration shown in FIG. 10 is only an example. The tracker circuitry 1A can be implemented by using any of a variety of circuit implementations and circuit technologies. Hence, the following explanation of the tracker circuitry 1A is not to be interpreted in a limited manner.

The tracker circuitry 1A according to the first modified example includes a first filter circuit 41A, a second filter circuit 42A, and a switch S56D, instead of the first filter circuit 41, the second filter circuit 42, and the switch S56C in the second embodiment.

The first filter circuit 41A is connected to the first path 441 and to the second path 442. More specifically, the first filter circuit 41A is connected between the first and second paths 441 and 442 and a ground. One end of a series circuit of an inductor L51A and a capacitor C51A of the first filter circuit 41A is connected to the first and second paths 441 and 442, and the other end of the series circuit is connected to a ground.

The second filter circuit 42A is connected to each of the first and second paths 441 and 442 in a switchable manner. More specifically, the second filter circuit 42A is connected between the first and second paths 441 and 442 and a ground via the switch S56D. One end of a series circuit of an inductor L52A and a capacitor C52A of the second filter circuit 42A is connected to the first and second paths 441 and 442 via the switch S56D. The other end of the series circuit of the inductor L52A and the capacitor C52A is connected to a ground.

The switch S56D is an example of the first switch and is an ON/OFF switch for the second filter circuit 42A. The switch S56D is connected between the second path 442 and the second filter circuit 42A.

The first and second filter circuits 41A and 42A connected in this manner are switched between ON and OFF by the switch S56D. The first and second filter circuits 41A and 42A can thus change the attenuation band of a band elimination filter used for removing noise from multiple discrete voltages. That is, the first and second filter circuits 41A and 42A function as a variable filter circuit that can switch between multiple attenuation bands.

Under the opening/closing control of the switch S56D, the first and second filter circuits 41A and 42A of the first modified example can implement three types of band elimination filters indicated by the following modes (i), (ii), and (iii).
(i) When the first power amplifier 2A amplifies the radio-frequency signal RF1, the switch S56D is opened so that the first filter circuit 41A is connected to the first path 441 and the second filter circuit 42A is not connected to the first path 441. Then, on the first path 441, the first filter circuit 41A functions as a band elimination filter, while the second filter circuit 42A does not function as a band elimination filter.
(ii) When the first power amplifier 2A amplifies the radio-frequency signal RF1, the switch S56D is closed so that the first and second filter circuits 41A and 42A are connected to the first path 441. Then, on the first path 441, the first and second filter circuits 41A and 42A function as a band elimination filter.
(iii) When the second power amplifier 2B amplifies the radio-frequency signal RF2, the switch S56D is closed so that the first and second filter circuits 41A and 42A are connected to the second path 442. Then, on the second path 442, the first and second filter circuits 41A and 42A function as a band elimination filter.
(iv) When the second power amplifier 2B amplifies the radio-frequency signal RF2, the switch S56D is opened so that the first filter circuit 41A is connected to the second path 442 and the second filter circuit 42A is not connected to the second path 442. Then, on the second path 442, the first filter circuit 41A functions as a band elimination filter, while the second filter circuit 42A does not function as a band elimination filter.

As in the switch S56C of the second embodiment, the opening/closing of the switch S56D can be controlled based on the power amplifier used for amplifying a radio-frequency signal, the channel bandwidth of the radio-frequency signal, the frequency band of the radio-frequency signal, or a desired combination thereof, for example.

The DPD circuit 71 of the first modified example can switch between the DPD mathematical-expression models and/or between their parameter sets in accordance with the above-described modes (i) through (iv). In the first modified example, the relationships between the ON/OFF states of the first and second power amplifiers 2A and 2B, the ON/OFF states of the first and second filter circuits 41A and 42A, and the parameter sets used for the corresponding DPD mathematical-expression models can be summarized as in the following Table 6.

TABLE 6

| | First | Second | First | Second | |
|---|---|---|---|---|---|
| | power | power | filter | filter | |
| | amplifier | amplifier | circuit | circuit | DPD |
| (i) | ON | OFF | ON | OFF | First mathematical- |
| | | | | | expression model |
| | | | | | First parameter set |
| (ii) | ON | OFF | ON | ON | Second mathematical- |
| | | | | | expression model |
| | | | | | Second parameter set |
| (iii) | OFF | ON | ON | ON | Third mathematical- |
| | | | | | expression model |
| | | | | | Third parameter set |
| (iv) | OFF | ON | ON | OFF | Fourth mathematical- |
| | | | | | expression model |
| | | | | | Fourth parameter set |

In Table 6, the first through fourth mathematical-expression models may be different from each other, or among the four mathematical-expression models, any desired combination of mathematical-expression models may be the same. The first through fourth parameter sets are at least partially different from each other.

The tracker circuitry 1A may also include an additional switch connected between the first path 441 and the first filter circuit 41A. In this case, the first and second filter circuits 41A and 42A can implement band elimination filters of the following modes (v) and (vi) in addition to the modes (i) through (iv).
(v) When the first power amplifier 2A amplifies the radio-frequency signal RF1, the additional switch is opened and the switch S56D is closed so that the first filter circuit 41A is not connected to the first path 441 and the second filter circuit 42A is connected to the first path 441. Then, on the first path 441, the first filter circuit 41A does not function as a band elimination filter, while the second filter circuit 42A functions as a band elimination filter.
(vi) When the second power amplifier 2B amplifies the radio-frequency signal RF2, the additional switch is opened and the switch S56D is closed so that the first filter circuit 41A is not connected to the second path 442 and the second filter circuit 42A is connected to the second path 442. Then, on the second path 442, the first filter circuit 41A does not function as a band elimination filter, while the second filter circuit 42A functions as a band elimination filter.

### 6.2 Advantages and Others

As described above, in the power amplification system 7A according to the first modified example, the first filter circuit 41A may be connected between the first path 441 and a ground, while the second filter circuit 42A may be connected between the second path 442 and a ground. The power amplification system 7A may also include the switch S56D connected between the second path 442 and the second filter circuit 42A.

With this configuration, when the first filter circuit 41A is shunt-connected to the first path 441 and when the second filter circuit 42A is shunt-connected to the second path 442, the nonlinear distortion in the first and second power amplifiers 2A and 2B can be reduced.

### Second Modified Example of Second Exemplary Embodiment

A second modified example of the second embodiment will now be described below. The second modified example is different from the second embodiment and the first modified example thereof mainly in the circuit configurations of the first and second filter circuits. Hereinafter, the second modified example will be discussed below with reference to the drawing mainly by referring to the points different from the second embodiment and the first modified example thereof.

The circuit configuration of the communication apparatus 6A according to the second modified example is similar to that of the second embodiment, except for part of the tracker circuitry 1A, and an explanation and illustration thereof will thus be omitted unless necessary.

### 7.1 Circuit Configuration of Tracker Circuitry 1A

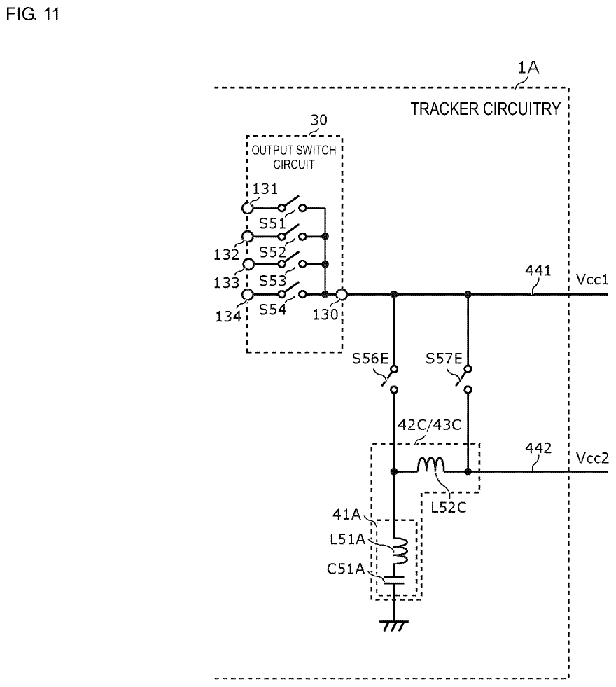

The circuit configuration of the tracker circuitry 1A according to the second modified example will be described below with reference to FIG. 11. FIG. 11 is a partial circuit diagram of the tracker circuitry 1A according to the second modified example.

The circuit configuration shown in FIG. 11 is only an example. The tracker circuitry 1A can be implemented by using any of a variety of circuit implementations and circuit technologies. Hence, the following explanation of the tracker circuitry 1A is not to be interpreted in a limited manner.

The tracker circuitry 1A according to the second modified example includes a first filter circuit 41A, a second filter circuit 42C, a third filter circuit 43C, and switches S56E and S57E, instead of the first filter circuit 41, the second filter circuit 42, and the switch S56C in the second embodiment.

The first filter circuit 41A is connected to the first path 441 in a switchable manner. More specifically, one end of a series circuit of an inductor L51A and a capacitor C51A of the first filter circuit 41A is connected to the first path 441 via the switch S56E, and the other end of the series circuit is connected to a ground.

The second filter circuit 42C is connected to each of the first and second paths 441 and 442 in a switchable manner. More specifically, the second filter circuit 42C includes a series circuit of an inductor L52C, the inductor L51A, and the capacitor C51A. One end of the series circuit of the inductor L52C, the inductor L51A, and the capacitor C51A is connected to the first and second paths 441 and 442 via the switch S57E. The other end of the series circuit is connected to a ground.

The third filter circuit 43C is connected to the second path 442 in a switchable manner. More specifically, the third filter circuit 43C includes the inductor L52C and the series circuit of the inductor L51A and the capacitor C51A. One end of the inductor L52C is connected to the output switch circuit 30 via the switch S56E, and the other end thereof is connected to the second power amplifier 2B. One end of the series circuit of the inductor L51A and the capacitor C51A is connected to the second path 442 via the switch S56E, and the other end of the series circuit is connected to a ground. That is, the third filter circuit 43C is different from the second filter circuit 42C in that the inductor L52C is not shunt-connected to the second path 442, but is connected in series with the second path 442.

The switch S56E is an ON/OFF switch for the first and third filter circuits 41A and 43C. The switch S56E is connected between the first path 441 and the first filter circuit 41A and is connected between the output switch circuit 30 and the third filter circuit 43C. That is, one end of the switch S56E is connected to the first path 441 and to the output switch circuit 30, and the other end thereof is connected to the inductors L51A and L52C.

The switch S57E is an ON/OFF switch for the second filter circuit 42C. The switch S57E is connected between the first path 441 and the second filter circuit 42C and is connected between the output switch circuit 30 and the second power amplifier 2B. That is, one end of the switch S57E is connected to the first path 441 and to the output switch circuit 30, and the other end thereof is connected to the inductor L52C and to the second power amplifier 2B.

The first, second, and third filter circuits 41A, 42C, and 43C connected in this manner are switched between ON and OFF by the switches S56E and S57E. The first, second, and third filter circuits 41A, 42C, and 43C can thus change the attenuation band of a band elimination filter used for removing noise from multiple discrete voltages. That is, the first, second, and third filter circuits 41A, 42C, and 43C function as a variable filter circuit that can switch between multiple attenuation bands.

Under the opening/closing control of the switches S56E and S57E, the first, second, and third filter circuits 41A, 42C, and 43C of the second modified example can implement four types of band elimination filters indicated by the following modes (i) through (iv).
(i) When the first power amplifier 2A amplifies the radio-frequency signal RF1, the switch S56E is closed and the switch S57E is opened so that the first filter circuit 41A is connected to the first path 441 and the second filter circuit 42C is not connected to the first path 441. Then, on the first path 441, the first filter circuit 41A functions as a band elimination filter, while the second filter circuit 42C does not function as a band elimination filter.
(ii) When the first power amplifier 2A amplifies the radio-frequency signal RF1, the switch S56E is opened and the switch S57E is closed so that the first filter circuit 41A is not connected to the first path 441 and the second filter circuit 42C is connected to the first path 441. Then, on the first path 441, the second filter circuit 42C functions as a band elimination filter.
(iii) When the second power amplifier 2B amplifies the radio-frequency signal RF2, the switch S56E is opened and the switch S57E is closed so that the second filter circuit 42C is connected to the second path 442 and the third filter circuit 43C is not connected to the second path 442. Then, on the second path 442, the second filter circuit 42C functions as a band elimination filter.
(iv) When the second power amplifier 2B amplifies the radio-frequency signal RF2, the switch S56E is closed and the switch S57E is opened so that the second filter circuit 42C is not connected to the second path 442 and the third filter circuit 43C is connected to the second path 442. Then, on the second path 442, the third filter circuit 43C functions as a band elimination filter.

As in the switch S56C of the second embodiment, the opening/closing of the switches S56E and S57E can be controlled based on the power amplifier used for amplifying a radio-frequency signal, the channel bandwidth of the radio-frequency signal, the frequency band of the radio-frequency signal, or a desired combination thereof, for example.

In the second modified example, the DPD circuit 71 can switch between the DPD mathematical-expression models and/or between their parameter sets in accordance with the above-described modes (i) through (iv). In the second modified example, the relationships between the ON/OFF states of the first and second power amplifiers 2A and 2B, the ON/OFF states of the first, second, and third filter circuits 41A, 42C, and 43C, and the parameter sets used for the corresponding DPD mathematical-expression models can be summarized as in the following Table 7.

TABLE 7

| | First | Second | First | Second | Third | |
|---|---|---|---|---|---|---|
| | power | power | filter | filter | filter | |
| | amplifier | amplifier | circuit | circuit | circuit | DPD |
| (i) | ON | OFF | ON | OFF | — | First mathematical- |
| | | | | | | expression model |
| | | | | | | First parameter set |
| (ii) | ON | OFF | OFF | ON | — | Second mathematical- |
| | | | | | | expression model |
| | | | | | | Second parameter set |
| (iii) | OFF | ON | — | ON | OFF | Third mathematical- |
| | | | | | | expression model |
| | | | | | | Third parameter set |
| (iv) | OFF | ON | — | OFF | ON | Fourth mathematical- |
| | | | | | | expression model |
| | | | | | | Fourth parameter set |

In Table 7, the first through fourth mathematical-expression models may be different from each other, or among the four mathematical-expression models, any desired combination of mathematical-expression models may be the same. The first through fourth parameter sets are at least partially different from each other.

### 7.2 Advantages and Others

As described above, the power amplification system 7A according to the second modified example may also include the third filter circuit 43C. The first filter circuit 41A may include a series circuit of the inductor L51A and the capacitor C51A which are connected between the first path 441 and a ground in a switchable manner. The second filter circuit 42C may include a series circuit of the inductors L51A and L52C and the capacitor C51A which are connected between the first and second paths 441 and 442 and a ground in a switchable manner. The third filter circuit 43C may include a series circuit of the inductor L51A and the capacitor C51A and the inductor L52C which is connected between the output switch circuit 30 and the second power amplifier 2B. The power amplification system 7A may also include the switch S56E connected between the first path 441 and the first filter circuit 41A and the switch S57E connected between the first path 441 and the second filter circuit 42C.

With this configuration, when each of the first filter circuit 41A and the second filter circuit 42C is connected to the first path 441 in a switchable manner and when each of the second filter circuit 42C and the third filter circuit 43C is connected to the second path 442 in a switchable manner, the nonlinear distortion in the first and second power amplifiers 2A and 2B can be reduced.

### Third Exemplary Embodiment

A third embodiment will now be described below. The third embodiment is different from the above-described first and second embodiments mainly in that a power supply voltage is supplied to three power amplifiers from the tracker circuitry. Hereinafter, the third embodiment will be discussed below with reference to drawings mainly by referring to the points different from the first and second embodiments.

### 8.1 Circuit Configuration of Communication Apparatus 6B

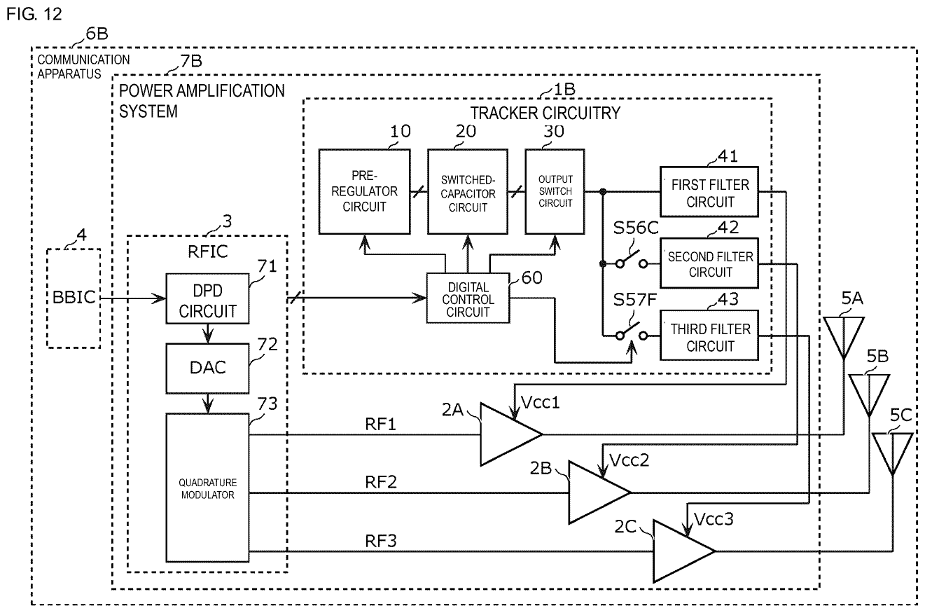

The circuit configuration of a communication apparatus 6B according to the third embodiment will first be explained below with reference to FIG. 12. FIG. 12 is a circuit diagram of the communication apparatus 6B according to the third embodiment.

The circuit configuration shown in FIG. 12 is only an example. The communication apparatus 6B can be implemented by using any of a variety of circuit implementations and circuit technologies. Hence, the following explanation of the communication apparatus 6B is not to be interpreted in a limited manner.

As illustrated in FIG. 12, the communication apparatus 6B includes tracker circuitry 1B, first, second, and third power amplifiers 2A, 2B, and 2C, an RFIC 3, a BBIC 4, and antennas 5A, 5B, and 5C. A power amplification system 7B includes the tracker circuitry 1B, the first, second, and third power amplifiers 2A, 2B, and 2C, and the RFIC 3.

Based on a tracking mode, the tracker circuitry 1B is able to supply multiple discrete voltages to the first, second, and third power amplifiers 2A, 2B, and 2C as power supply voltages Vcc1, Vcc2, and Vcc3, respectively. The power supply voltages Vcc1, Vcc2, and Vcc3 are supplied to the first, second, and third power amplifiers 2A, 2B, and 2C mutually exclusively. In the third embodiment, as the tracking mode, the D-ET mode and the APT mode are used. However, the tracking mode to be used is not limited to these modes.

The first power amplifier 2A is connected between the RFIC 3 and the antenna 5A. The first power amplifier 2A is also connected to the tracker circuitry 1B. The first power amplifier 2A is able to amplify a radio-frequency signal RF1 (an example of the first input signal) supplied from the RFIC 3 by using the power supply voltage Vcc1 supplied from the tracker circuitry 1B.

The second power amplifier 2B is connected between the RFIC 3 and the antenna 5B. The second power amplifier 2B is also connected to the tracker circuitry 1B. The second power amplifier 2B is able to amplify a radio-frequency signal RF2 (an example of the second input signal) supplied from the RFIC 3 by using the power supply voltage Vcc2 supplied from the tracker circuitry 1B.

The third power amplifier 2C is connected between the RFIC 3 and the antenna 5C. The third power amplifier 2C is also connected to the tracker circuitry 1B. The third power amplifier 2C is able to amplify a radio-frequency signal RF3 (an example of a third input signal) supplied from the RFIC 3 by using the power supply voltage Vcc3 supplied from the tracker circuitry 1B.

The RFIC 3 is an example of a signal processing circuit that processes a radio-frequency signal. The RFIC 3 can receive a digital IQ signal from the BBIC 4 and supply the radio-frequency signal RF1 to the first power amplifier 2A. The RFIC 3 can also receive a digital IQ signal from the BBIC 4 and supply the radio-frequency signal RF2 to the second power amplifier 2B. The RFIC 3 can also receive a digital IQ signal from the BBIC 4 and supply the radio-frequency signal RF3 to the third power amplifier 2C. The internal configuration of the RFIC 3 is similar to that of the first embodiment and an explanation thereof will thus be omitted.

The BBIC 4 is a baseband signal processing circuit that performs signal processing by using a frequency band lower than the radio-frequency signals RF1 through RF3. The BBIC 4 performs digital modulation on a bit sequence which represents an image signal for displaying an image and/or an audio signal for performing communication via a speaker, thereby generating a digital IQ signal. The generated IQ signal is supplied to the RFIC 3. The BBIC 4 may be omitted from the communication apparatus 6B.

The antenna 5A sends the radio-frequency signal RF1 amplified by the first power amplifier 2A to the outside of the communication apparatus 6B. The antenna 5B sends the radio-frequency signal RF2 amplified by the second power amplifier 2B to the outside of the communication apparatus 6B. The antenna 5C sends the radio-frequency signal RF3 amplified by the third power amplifier 2C to the outside of the communication apparatus 6B. The antennas 5A, 5B, and 5C or a desired combination thereof may be omitted from the communication apparatus 6B.

### 8.2 Circuit Configuration of Tracker Circuitry 1B

The circuit configuration of the tracker circuitry 1B will be described below with reference to FIG. 12. The tracker circuitry 1B includes a pre-regulator circuit 10, a switched-capacitor circuit 20, an output switch circuit 30, a first filter circuit 41, a second filter circuit 42, a third filter circuit 43, switches S56C and S57F, and a digital control circuit 60. The pre-regulator circuit 10, the switched-capacitor circuit 20, and the digital control circuit 60 are similar to the counterparts of the first embodiment and an explanation thereof will thus be omitted.

The output switch circuit 30 can selectively output at least one of multiple discrete voltages generated by the switched-capacitor circuit 20 to the first through third power amplifiers 2A through 2C mutually exclusively.

The first, second, and third filter circuits 41, 42, and 43 can attenuate noise from multiple discrete voltages to be supplied to the first, second, and third power amplifiers 2A, 2B, and 2C, respectively.

The switch S56C is an example of the first switch and is an ON/OFF switch for the second filter circuit 42. The switch S57F is an example of the second switch and is an ON/OFF switch for the third filter circuit 43. The switch S56C is connected between the output switch circuit 30 and the second filter circuit 42. The switch S57F is connected between the output switch circuit 30 and the third filter circuit 43.

### 8.2.1 Circuit Configuration of Third Filter Circuit 43

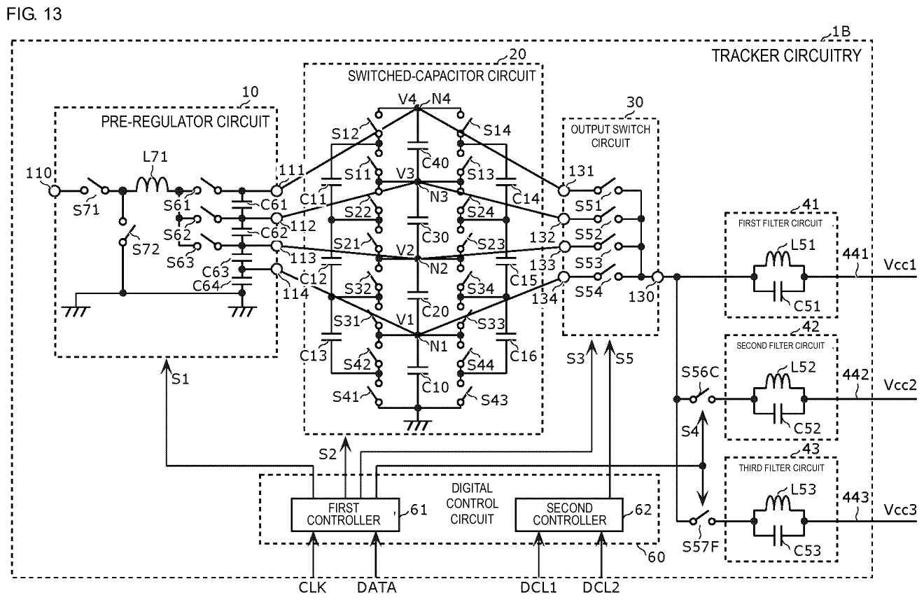

The circuit configuration of the third filter circuit 43 included in the tracker circuitry 1B will be explained below with reference to FIG. 13. FIG. 13 is a circuit diagram of the tracker circuitry 1B according to the third embodiment.

The circuit configuration shown in FIG. 13 is only an example. The tracker circuitry 1B can be implemented by using any of a variety of circuit implementations and circuit technologies. Hence, the following explanation of the tracker circuitry 1B is not to be interpreted in a limited manner.

The pre-regulator circuit 10, switched-capacitor circuit 20, output switch circuit 30, first and second filter circuits 41 and 42, and digital control circuit 60 are similar to the counterparts of the first or second embodiment and an explanation thereof will thus be omitted.

The third filter circuit 43 is connected in a switchable manner to each of a first path 441, a second path 442, and a third path 443 (an example of a third path), which connects the output switch circuit 30 and the third power amplifier 2C. More specifically, the third filter circuit 43 is connected between the output switch circuit 30 and the third power amplifier 2C via the switch S57F. The third filter circuit 43 includes a parallel circuit of an inductor L53 and a capacitor C53. One end of the parallel circuit of the inductor L53 and the capacitor C53 is connected to the output switch circuit 30 via the switch S57F. The other end of the parallel circuit is connected to the third power amplifier 2C. The third filter circuit 43 is not limited to an LC parallel circuit.

The third filter circuit 43 connected in this manner is switched between ON and OFF by the switch S57F. On the first through third paths 441 through 443, the third filter circuit 43 can thus change the attenuation band of a band elimination filter used for removing noise from multiple discrete voltages. That is, the first, second, and third filter circuits 41, 42, and 43 function as a variable filter circuit that can switch between multiple attenuation bands.

Under the opening/closing control of the switches S56C and S57F, the first, second, and third filter circuits 41, 42, and 43 of the third embodiment can implement eight types of band elimination filters indicated by the following modes (i) through (viii).
(i) When the first power amplifier 2A amplifies the radio-frequency signal RF1, the switches S56C and S57F are opened so that the first filter circuit 41 is connected to the first path 441 and the second and third filter circuits 42 and 43 are not connected to the first path 441. Then, on the first path 441, the first filter circuit 41 functions as a band elimination filter, while the second and third filter circuits 42 and 43 do not function as a band elimination filter.
(ii) When the first power amplifier 2A amplifies the radio-frequency signal RF1, the switch S56C is closed and the switch S57F is opened so that the first and second filter circuits 41 and 42 are connected to the first path 441 and the third filter circuit 43 is not connected to the first path 441. Then, on the first path 441, the first and second filter circuits 41 and 42 function as a band elimination filter, while the third filter circuit 43 does not function as a band elimination filter.
(iii) When the first power amplifier 2A amplifies the radio-frequency signal RF1, the switch S56C is opened and the switch S57F is closed so that the first and third filter circuits 41 and 43 are connected to the first path 441 and the second filter circuit 42 is not connected to the first path 441. Then, on the first path 441, the first and third filter circuits 41 and 43 function as a band elimination filter, while the second filter circuit 42 does not function as a band elimination filter.
(iv) When the first power amplifier 2A amplifies the radio-frequency signal RF1, the switches S56C and S57F are closed so that the first filter circuit 41, the second filter circuit 42, and the third filter circuit 43 are connected to the first path 441. Then, on the first path 441, the first, second, and third filter circuits 41, 42, and 43 function as a band elimination filter.
(v) When the second power amplifier 2B amplifies the radio-frequency signal RF2, the switch S56C is closed and the switch S57F is opened so that the first and second filter circuits 41 and 42 are connected to the second path 442 and the third filter circuit 43 is not connected to the second path 442. Then, on the second path 442, the first and second filter circuits 41 and 42 function as a band elimination filter, while the third filter circuit 43 does not function as a band elimination filter.
(vi) When the second power amplifier 2B amplifies the radio-frequency signal RF2, the switches S56C and S57F are closed so that the first filter circuit 41, the second filter circuit 42, and the third filter circuit 43 are connected to the second path 442. Then, on the second path 442, the first, second, and third filter circuits 41, 42, and 43 function as a band elimination filter.
(vii) When the third power amplifier 2C amplifies the radio-frequency signal RF3, the switch S56C is opened and the switch S57F is closed so that the first and third filter circuits 41 and 43 are connected to the third path 443 and the second filter circuit 42 is not connected to the third path 443. Then, on the third path 443, the first and third filter circuits 41 and 43 function as a band elimination filter, while the second filter circuit 42 does not function as a band elimination filter.
(viii) When the third power amplifier 2C amplifies the radio-frequency signal RF3, the switches S56C and S57F are closed so that the first filter circuit 41, the second filter circuit 42, and the third filter circuit 43 are connected to the third path 443. Then, on the third path 443, the first, second, and third filter circuits 41, 42, and 43 function as a band elimination filter.

As in the switch S56C of the second embodiment, the opening/closing of the switches S56C and S57F can be controlled based on the power amplifier used for amplifying a radio-frequency signal, the channel bandwidth of the radio-frequency signal, the frequency band of the radio-frequency signal, or a desired combination thereof, for example.

The DPD circuit 71 according to the third embodiment can switch between the DPD mathematical-expression models and/or between their parameter sets in accordance with the above-described modes (i) through (viii). In the third embodiment, the relationships between the ON/OFF states of the first, second, and third power amplifiers 2A, 2B, and 2C, the ON/OFF states of the first, second, and third filter circuits 41, 42, and 43, and the parameter sets used for the corresponding DPD mathematical-expression models can be summarized as in the following Table 8.

TABLE 8

| | First | Second | Third | First | Second | Third | |
|---|---|---|---|---|---|---|---|
| | power | power | power | filter | filter | filter | |
| | amplifier | amplifier | amplifier | circuit | circuit | circuit | DPD |
| (i) | ON | OFF | OFF | ON | OFF | OFF | First mathematical- |
| | | | | | | | expression model |
| | | | | | | | First parameter set |
| (ii) | ON | OFF | OFF | ON | ON | OFF | Second mathematical- |
| | | | | | | | expression model |
| | | | | | | | Second parameter set |
| (iii) | ON | OFF | OFF | ON | OFF | ON | Third mathematical- |
| | | | | | | | expression model |
| | | | | | | | Third parameter set |
| (iv) | ON | OFF | OFF | ON | ON | ON | Fourth mathematical- |
| | | | | | | | expression model |
| | | | | | | | Fourth parameter set |
| (v) | OFF | ON | OFF | ON | ON | OFF | Fifth mathematical- |
| | | | | | | | expression model |
| | | | | | | | Fifth parameter set |
| (vi) | OFF | ON | OFF | ON | ON | ON | Sixth mathematical- |
| | | | | | | | expression model |
| | | | | | | | Sixth parameter set |
| (vii) | OFF | OFF | ON | ON | OFF | ON | Seventh mathematical- |
| | | | | | | | expression model |
| | | | | | | | Seventh parameter set |
| (viii) | OFF | OFF | ON | ON | ON | ON | Eighth mathematical- |
| | | | | | | | expression model |
| | | | | | | | Eighth parameter set |

In Table 8, the first through eighth mathematical-expression models may be different from each other, or among the eight mathematical-expression models, any desired combination of mathematical-expression models may be the same. The first through eighth parameter sets are at least partially different from each other.

The tracker circuitry 1B may also include an additional switch connected between the output switch circuit 30 and the first filter circuit 41. In this case, the first, second, and third filter circuits 41, 42, and 43 can implement band elimination filters of the following modes (ix) through (xii) in addition to the modes (i) through (viii).
(ix) When the second power amplifier 2B amplifies the radio-frequency signal RF2, the additional switch and the switch S57F are opened and the switch S56C is closed so that the first filter circuit 41 and the third filter circuit 43 are not connected to the second path 442 and the second filter circuit 42 is connected to the second path 442. Then, on the second path 442, the first and third filter circuits 41 and 43 do not function as a band elimination filter, while the second filter circuit 42 functions as a band elimination filter.
(x) When the second power amplifier 2B amplifies the radio-frequency signal RF2, the additional switch is opened and the switches S56C and S57F are closed so that the first filter circuit 41 is not connected to the second path 442 and the second and third filter circuits 42 and 43 are connected to the second path 442. Then, on the second path 442, the first filter circuit 41 does not function as a band elimination filter, while the second and third filter circuits 42 and 43 function as a band elimination filter.
(xi) When the third power amplifier 2C amplifies the radio-frequency signal RF3, the additional switch and the switch S56C are opened and the switch S57F is closed so that the first filter circuit 41 and the second filter circuit 42 are not connected to the third path 443 and the third filter circuit 43 is connected to the third path 443. Then, on the third path 443, the first and second filter circuits 41 and 42 do not function as a band elimination filter, while the third filter circuit 43 functions as a band elimination filter.
(xii) When the third power amplifier 2C amplifies the radio-frequency signal RF3, the additional switch is opened and the switches S56C and S57F are closed so that the first filter circuit 41 is not connected to the third path 443 and the second and third filter circuits 42 and 43 are connected to the third path 443. Then, on the third path 443, the first filter circuit 41 does not function as a band elimination filter, while the second and third filter circuits 42 and 43 function as a band elimination filter.

### 8.3 Advantages and Others

As described above, the power amplification system 7B according to the third embodiment includes the first, second, and third power amplifiers 2A, 2B, and 2C, the output switch circuit 30, the first, second, and third filter circuits 41, 42, and 43, and the DPD circuit. The output switch circuit 30 is configured to selectively output at least one of multiple discrete voltages to the first, second, and third power amplifiers 2A, 2B, and 2C.

The first filter circuit 41 is connected to the first path 441, which connects the output switch circuit 30 and the first power amplifier 2A, and is also connected to the second path 442, which connects the output switch circuit 30 and the second power amplifier 2B, and is also connected to the third path 443, which connects the output switch circuit 30 and the third power amplifier 2C. The second filter circuit 42 is connected to the first path 441 in a switchable manner, and is also connected to the second path 442 in a switchable manner, and is also connected to the third path 443 in a switchable manner. The third filter circuit 43 is connected to the first path 441 in a switchable manner, and is also connected to the second path 442 in a switchable manner, and is also connected to the third path 443 in a switchable manner. The DPD circuit is configured to predistort a first input signal to be supplied to the first power amplifier 2A, a second input signal to be supplied to the second power amplifier 2B, and a third input signal to be supplied to the third power amplifier 2C. In a case in which the first power amplifier 2A amplifies the first input signal: (i) when the second and third filter circuits 42 and 43 are not connected to the first path 441, the DPD circuit predistorts the first input signal by using a first parameter set for a first mathematical-expression model; (ii) when the second filter circuit 42 is connected to the first path 441 and when the third filter circuit 43 is not connected to the first path 441, the DPD circuit predistorts the first input signal by using a second parameter set for a second mathematical-expression model; (iii) when the second filter circuit 42 is not connected to the first path 441 and when the third filter circuit 43 is connected to the first path 441, the DPD circuit predistorts the first input signal by using a third parameter set for a third mathematical-expression model; and (iv) when the second and third filter circuits 42 and 43 are connected to the first path 441, the DPD circuit predistorts the first input signal by using a fourth parameter set for a fourth mathematical-expression model. In a case in which the second power amplifier 2B amplifies the second input signal: (v) when the second filter circuit 42 is connected to the second path 442 and when the third filter circuit 43 is not connected to the second path 442, the DPD circuit predistorts the second input signal by using a fifth parameter set for a fifth mathematical-expression model; and (vi) when the second and third filter circuits 42 and 43 are connected to the second path 442, the DPD circuit predistorts the second input signal by using a sixth parameter set for a sixth mathematical-expression model. In a case in which the third power amplifier 2C amplifies the third input signal: (vii) when the second filter circuit 42 is not connected to the third path 443 and when the third filter circuit 43 is connected to the third path 443, the DPD circuit predistorts the third input signal by using a seventh parameter set for a seventh mathematical-expression model; and (viii) when the second and third filter circuits 42 and 43 are connected to the third path 443, the DPD circuit predistorts the third input signal by using an eighth parameter set for an eighth mathematical-expression model. The first through eighth parameter sets are at least partially different from each other.

With this configuration, the mathematical-expression models and/or parameter sets can be switched therebetween in accordance with whether the second filter circuit 42 is connected to the first path 441, which is used for supplying multiple discrete voltages to the first power amplifier 2A, and whether the third filter circuit 43 is connected to the first path 441. It is thus possible to predistort the input signal to be supplied to the first power amplifier 2A by using the mathematical-expression model and the parameter set suitable for the first power amplifier 2A whose linearity is changed according to whether the second filter circuit 42 is connected to or disconnected from the first path 441 and whether the third filter circuit 43 is connected to or disconnected from the first path 441. This can reduce the nonlinear distortion in the first power amplifier 2A. According to the third embodiment, the mathematical-expression models and/or parameter sets can be switched therebetween in accordance with whether the third filter circuit 43 is connected to the second path 442, which is used for supplying multiple discrete voltages to the second power amplifier 2B. It is thus possible to predistort the input signal to be supplied to the second power amplifier 2B by using the mathematical-expression model and the parameter set suitable for the second power amplifier 2B whose linearity is changed according to whether the third filter circuit 43 is connected to or disconnected from the second path 442. This can reduce the nonlinear distortion in the second power amplifier 2B. According to the third embodiment, the mathematical-expression models and/or parameter sets can be switched therebetween in accordance with whether the second filter circuit 42 is connected to the third path 443, which is used for supplying multiple discrete voltages to the third power amplifier 2C. It is thus possible to predistort the input signal to be supplied to the third power amplifier 2C by using the mathematical-expression model and the parameter set suitable for the third power amplifier 2C whose linearity is changed according to whether the second filter circuit 42 is connected to or disconnected from the third path 443. This can reduce the nonlinear distortion in the third power amplifier 2C. Additionally, according to the third embodiment, the mathematical-expression models and/or parameter sets can be switched therebetween in accordance with whether the first, second, or third power amplifier 2A, 2B, or 2C is used. It is thus possible to predistort the input signal to be supplied to the first power amplifier 2A by using the mathematical-expression model and the parameter set suitable for the first power amplifier 2A, and also to predistort the input signal to be supplied to the second power amplifier 2B by using the mathematical-expression model and the parameter set suitable for the second power amplifier 2B, and also to predistort the input signal to be supplied to the third power amplifier 2C by using the mathematical-expression model and the parameter set suitable for the third power amplifier 2C. This can reduce the nonlinear distortion in the first, second, and third power amplifiers 2A, 2B, and 2C.

Additionally, in one example, in the power amplification system 7B according to the third embodiment: the first filter circuit 41 may be connected between the output switch circuit 30 and the first power amplifier 2A; the second filter circuit 42 may be connected between the output switch circuit 30 and the second power amplifier 2B; and the third filter circuit 43 may be connected between the output switch circuit 30 and the third power amplifier 2C. The power amplification system 7B may also include the switch S56C connected between the output switch circuit 30 and the second filter circuit 42 and the switch S57F connected between the output switch circuit 30 and the third filter circuit 43.

With this configuration, when the first filter circuit 41 is connected in series with the first path 441, and when the second filter circuit 42 is connected in series with the second path 442, and when the third filter circuit 43 is connected in series with the third path 443, the nonlinear distortion in the first, second, and third power amplifiers 2A, 2B, and 2C can be reduced.

Additionally, in a case in which the first power amplifier 2A amplifies the first input signal: (i) when the second and third filter circuits 42 and 43 are not connected to the first path 441, the DPD circuit 71 of the third embodiment predistorts the first input signal by using the first parameter set for the first mathematical-expression model; (ii) when the second filter circuit 42 is connected to the first path 441 and when the third filter circuit 43 is not connected to the first path 441, the DPD circuit 71 predistorts the first input signal by using the second parameter set for the second mathematical-expression model; (iii) when the second filter circuit 42 is not connected to the first path 441 and when the third filter circuit 43 is connected to the first path 441, the DPD circuit 71 predistorts the first input signal by using the third parameter set for the third mathematical-expression model; and (iv) when the second and third filter circuits 42 and 43 are connected to the first path 441, the DPD circuit 71 predistorts the first input signal by using the fourth parameter set for the fourth mathematical-expression model. In a case in which the second power amplifier 2B amplifies the second input signal: (v) when the second filter circuit 42 is connected to the second path 442 and when the third filter circuit 43 is not connected to the second path 442, the DPD circuit 71 predistorts the second input signal by using the fifth parameter set for the fifth mathematical-expression model; and (vi) when the second and third filter circuits 42 and 43 are connected to the second path 442, the DPD circuit 71 predistorts the second input signal by using the sixth parameter set for the sixth mathematical-expression model. In a case in which the third power amplifier 2C amplifies the third input signal: (vii) when the second filter circuit 42 is not connected to the third path 443 and when the third filter circuit 43 is connected to the third path 443, the DPD circuit 71 predistorts the third input signal by using the seventh parameter set for the seventh mathematical-expression model; and (viii) when the second and third filter circuits 42 and 43 are connected to the third path 443, the DPD circuit 71 predistorts the third input signal by using the eighth parameter set for the eighth mathematical-expression model. The first through eighth parameter sets are at least partially different from each other.

With this configuration, the mathematical-expression models and/or parameter sets can be switched therebetween in accordance with whether the second filter circuit 42 is connected to the first path 441, which is used for supplying multiple discrete voltages to the first power amplifier 2A, and whether the third filter circuit 43 is connected to the first path 441. It is thus possible to predistort the input signal to be supplied to the first power amplifier 2A by using the mathematical-expression model and the parameter set suitable for the first power amplifier 2A whose linearity is changed according to whether the second filter circuit 42 is connected to or disconnected from the first path 441 and whether the third filter circuit 43 is connected to or disconnected from the first path 441. This can reduce the nonlinear distortion in the first power amplifier 2A. According to the third embodiment, the mathematical-expression models and/or parameter sets can be switched therebetween in accordance with whether the third filter circuit 43 is connected to the second path 442, which is used for supplying multiple discrete voltages to the second power amplifier 2B. It is thus possible to predistort the input signal to be supplied to the second power amplifier 2B by using the mathematical-expression model and the parameter set suitable for the second power amplifier 2B whose linearity is changed according to whether the third filter circuit 43 is connected to or disconnected from the second path 442. This can reduce the nonlinear distortion in the second power amplifier 2B. According to the third embodiment, the mathematical-expression models and/or parameter sets can be switched therebetween in accordance with whether the second filter circuit 42 is connected to the third path 443, which is used for supplying multiple discrete voltages to the third power amplifier 2C. It is thus possible to predistort the input signal to be supplied to the third power amplifier 2C by using the mathematical-expression model and the parameter set suitable for the third power amplifier 2C whose linearity is changed according to whether the second filter circuit 42 is connected to or disconnected from the third path 443. This can reduce the nonlinear distortion in the third power amplifier 2C. Additionally, according to the third embodiment, the mathematical-expression models and/or parameter sets can be switched therebetween in accordance with whether the first, second, or third power amplifier 2A, 2B, or 2C is used. It is thus possible to predistort the input signal to be supplied to the first power amplifier 2A by using the mathematical-expression model and the parameter set suitable for the first power amplifier 2A, and also to predistort the input signal to be supplied to the second power amplifier 2B by using the mathematical-expression model and the parameter set suitable for the second power amplifier 2B, and also to predistort the input signal to be supplied to the third power amplifier 2C by using the mathematical-expression model and the parameter set suitable for the third power amplifier 2C. This can reduce the nonlinear distortion in the first, second, and third power amplifiers 2A, 2B, and 2C.

### First Modified Example of Third Exemplary Embodiment

A first modified example of the third embodiment will now be described below. The first modified example is different from the third embodiment mainly in the circuit configurations of the first, second, and third filter circuits. Hereinafter, the first modified example will be discussed below with reference to the drawing mainly by referring to the points different from the third embodiment and the first modified example of the second embodiment.

The circuit configuration of the communication apparatus 6B according to the first modified example of the third embodiment is similar to that of the first modified example of the second embodiment and the third embodiment, except for part of the tracker circuitry 1B, and an explanation and illustration thereof will thus be omitted unless necessary.

### 9.1 Circuit Configuration of Tracker Circuitry 1B

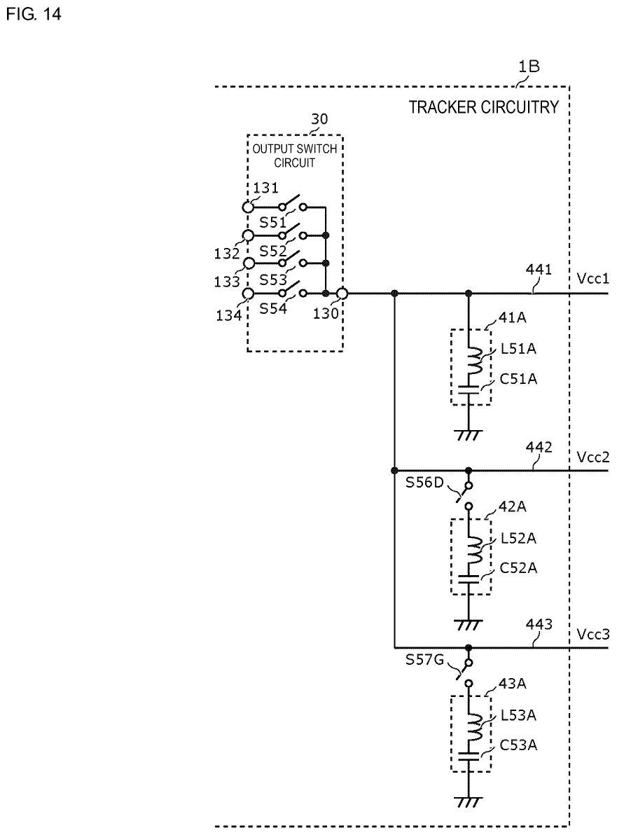

The circuit configuration of the tracker circuitry 1B according to the first modified example will be explained below with reference to FIG. 14. FIG. 14 is a partial circuit diagram of the tracker circuitry 1B according to the first modified example.

The circuit configuration shown in FIG. 14 is only an example. The tracker circuitry 1B can be implemented by using any of a variety of circuit implementations and circuit technologies. Hence, the following explanation of the tracker circuitry 1B is not to be interpreted in a limited manner.

The tracker circuitry 1B according to the first modified example includes a first filter circuit 41A, a second filter circuit 42A, a third filter circuit 43A, and switches S56D and S57G, instead of the first filter circuit 41, the second filter circuit 42, the third filter circuit 43, and the switches S56C and S57F in the third embodiment.

The third filter circuit 43A is connected to each of the first, second, and third paths 441, 442, and 443 in a switchable manner. More specifically, the third filter circuit 43A is connected between the first, second, and third paths 441, 442, and 443 and a ground via the switch S57G. The third filter circuit 43A includes a series circuit of an inductor L53A and a capacitor C53A. One end of the series circuit of the inductor L53A and the capacitor C53A is connected to the first, second, and third paths 441, 442, and 443 via the switch S57G. The other end of the series circuit is connected to a ground. The third filter circuit 43A is not limited to an LC series circuit.

The switch S57G is an example of the second switch and is an ON/OFF switch for the third filter circuit 43A. The switch S57G is connected between the third path 443 and the third filter circuit 43A.

The third filter circuit 43A connected in this manner is switched between ON and OFF by the switch S57G. On the first through third paths 441 through 443, the third filter circuit 43A can thus change the attenuation band of a band elimination filter used for removing noise from multiple discrete voltages. That is, the first, second, and third filter circuits 41A, 42A, and 43A function as a variable filter circuit that can switch between multiple attenuation bands.

Under the opening/closing control of the switches S56D and S57G, the first, second, and third filter circuits 41A, 42A, and 43A of the first modified example can implement twelve types of band elimination filters indicated by the following modes (i) through (xii).
(i) When the first power amplifier 2A amplifies the radio-frequency signal RF1, the switches S56D and S57G are opened so that the first filter circuit 41A is connected to the first path 441 and the second and third filter circuits 42A and 43A are not connected to the first path 441. Then, on the first path 441, the first filter circuit 41A functions as a band elimination filter, while the second and third filter circuits 42A and 43A do not function as a band elimination filter.
(ii) When the first power amplifier 2A amplifies the radio-frequency signal RF1, the switch S56D is closed and the switch S57G is opened so that the first and second filter circuits 41A and 42A are connected to the first path 441 and the third filter circuit 43A is not connected to the first path 441. Then, on the first path 441, the first and second filter circuits 41A and 42A function as a band elimination filter, while the third filter circuit 43A does not function as a band elimination filter.
(iii) When the first power amplifier 2A amplifies the radio-frequency signal RF1, the switch S56D is opened and the switch S57G is closed so that the first and third filter circuits 41A and 43A are connected to the first path 441 and the second filter circuit 42A is not connected to the first path 441. Then, on the first path 441, the first and third filter circuits 41A and 43A function as a band elimination filter, while the second filter circuit 42A does not function as a band elimination filter.
(iv) When the first power amplifier 2A amplifies the radio-frequency signal RF1, the switches S56D and S57G are closed so that the first filter circuit 41A, the second filter circuit 42A, and the third filter circuit 43A are connected to the first path 441. Then, on the first path 441, the first, second, and third filter circuits 41A, 42A, and 43A function as a band elimination filter.
(v) When the second power amplifier 2B amplifies the radio-frequency signal RF2, the switch S56D is closed and the switch S57G is opened so that the first and second filter circuits 41A and 42A are connected to the second path 442 and the third filter circuit 43 A is not connected to the second path 442. Then, on the second path 442, the first and second filter circuits 41A and 42A function as a band elimination filter, while the third filter circuit 43A does not function as a band elimination filter.
(vi) When the second power amplifier 2B amplifies the radio-frequency signal RF2, the switches S56D and S57G are closed so that the first filter circuit 41A, the second filter circuit 42A, and the third filter circuit 43A are connected to the second path 442. Then, on the second path 442, the first, second, and third filter circuits 41A, 42A, and 43A function as a band elimination filter.
(vii) When the third power amplifier 2C amplifies the radio-frequency signal RF3, the switch S56D is opened and the switch S57G is closed so that the first and third filter circuits 41A and 43A are connected to the third path 443 and the second filter circuit 42A is not connected to the third path 443. Then, on the third path 443, the first and third filter circuits 41A and 43A function as a band elimination filter, while the second filter circuit 42A does not function as a band elimination filter.
(viii) When the third power amplifier 2C amplifies the radio-frequency signal RF3, the switches S56D and S57G are closed so that the first filter circuit 41A, the second filter circuit 42A, and the third filter circuit 43A are connected to the third path 443. Then, on the third path 443, the first, second, and third filter circuits 41A, 42A, and 43A function as a band elimination filter.
(ix) When the second power amplifier 2B amplifies the radio-frequency signal RF2, the switches S56D and S57G are opened so that the first filter circuit 41A is connected to the second path 442 and the second filter circuit 42A and the third filter circuit 43A are not connected to the second path 442. Then, on the second path 442, the first filter circuit 41A functions as a band elimination filter, while the second and third filter circuits 42A and 43A do not function as a band elimination filter.
(x) When the second power amplifier 2B amplifies the radio-frequency signal RF2, the switch S56D is opened and the switch S57G is closed so that the first and third filter circuits 41A and 43A are connected to the second path 442 and the second filter circuit 42A is not connected to the second path 442. Then, on the second path 442, the first and third filter circuits 41A and 43A function as a band elimination filter, while the second filter circuit 42A does not function as a band elimination filter.
(xi) When the third power amplifier 2C amplifies the radio-frequency signal RF3, the switches S56D and S57G are opened so that the first filter circuit 41A is connected to the third path 443 and the second filter circuit 42A and the third filter circuit 43A are not connected to the third path 443. Then, on the third path 443, the first filter circuit 41A functions as a band elimination filter, while the second and third filter circuits 42A and 43A do not function as a band elimination filter.
(xii) When the third power amplifier 2C amplifies the radio-frequency signal RF3, the switch S56D is closed and the switch S57G is opened so that the first and second filter circuits 41A and 42A are connected to the third path 443 and the third filter circuit 43A is not connected to the third path 443. Then, on the third path 443, the first and second filter circuits 41A and 42A function as a band elimination filter, while the third filter circuit 43A does not function as a band elimination filter.

As in the switches S56C and S57F of the third embodiment, the opening/closing of the switches S56D and S57G can be controlled based on the power amplifier used for amplifying a radio-frequency signal, the channel bandwidth of the radio-frequency signal, the frequency band of the radio-frequency signal, or a desired combination thereof, for example.

The DPD circuit 71 according to the first modified example can switch between the DPD mathematical-expression models and/or between their parameter sets in accordance with the above-described modes (i) through (xii). In the first modified example, the relationships between the ON/OFF states of the first, second, and third power amplifiers 2A, 2B, and 2C, the ON/OFF states of the first, second, and third filter circuits 41A, 42A, and 43A, and the parameter sets used for the corresponding DPD mathematical-expression models can be summarized as in the following Table 9.

TABLE 9

| | First | Second | Third | First | Second | Third | |
|---|---|---|---|---|---|---|---|
| | power | power | power | filter | filter | filter | |
| | amplifier | amplifier | amplifier | circuit | circuit | circuit | DPD |
| (i) | ON | OFF | OFF | ON | OFF | OFF | First mathematical- |
| | | | | | | | expression model |
| | | | | | | | First parameter set |
| (ii) | ON | OFF | OFF | ON | ON | OFF | Second mathematical- |
| | | | | | | | expression model |
| | | | | | | | Second parameter set |
| (iii) | ON | OFF | OFF | ON | OFF | ON | Third mathematical- |
| | | | | | | | expression model |
| | | | | | | | Third parameter set |
| (iv) | ON | OFF | OFF | ON | ON | ON | Fourth mathematical- |
| | | | | | | | expression model |
| | | | | | | | Fourth parameter set |
| (v) | OFF | ON | OFF | ON | ON | OFF | Fifth mathematical- |
| | | | | | | | expression model |
| | | | | | | | Fifth parameter set |
| (vi) | OFF | ON | OFF | ON | ON | ON | Sixth mathematical- |
| | | | | | | | expression model |
| | | | | | | | Sixth parameter set |
| (vii) | OFF | OFF | ON | ON | OFF | ON | Seventh mathematical- |
| | | | | | | | expression model |
| | | | | | | | Seventh parameter set |
| (viii) | OFF | OFF | ON | ON | ON | ON | Eighth mathematical- |
| | | | | | | | expression model |
| | | | | | | | Eighth parameter set |
| (ix) | OFF | ON | OFF | ON | OFF | OFF | Ninth mathematical- |
| | | | | | | | expression model |
| | | | | | | | Ninth parameter set |
| (x) | OFF | ON | OFF | ON | OFF | ON | Tenth mathematical- |
| | | | | | | | expression model |
| | | | | | | | Tenth parameter set |
| (xi) | OFF | OFF | ON | ON | OFF | OFF | Eleventh mathematical- |
| | | | | | | | expression model |
| | | | | | | | Eleventh parameter set |
| (xii) | OFF | OFF | ON | ON | ON | OFF | Twelfth mathematical- |
| | | | | | | | expression model |
| | | | | | | | Twelfth parameter set |

In Table 9, the first through twelfth mathematical-expression models may be different from each other, or among the twelve mathematical-expression models, any desired combination of mathematical-expression models may be the same. The first through twelfth parameter sets are at least partially different from each other.

9.2 Advantages and Others

As described above, in the power amplification system 7B according to the first modified example: the first filter circuit 41A may be connected between the first path 441 and a ground; the second filter circuit 42A may be connected between the second path 442 and a ground; and the third filter circuit 43A may be connected between the third path 443 and a ground. The power amplification system 7B may also include the switch S56D connected between the second path 442 and the second filter circuit 42A and the switch S57G connected between the third path 443 and the third filter circuit 43A.

With this configuration, when the first, second, and third filter circuits 41A, 42A, and 43 A are shunt-connected to the first, second, and third paths 441, 442, and 443, respectively, the nonlinear distortion in the first, second, and third power amplifiers 2A, 2B, and 2C can be reduced.

### Additional Exemplary Embodiments

The power amplification systems and DPD methods according to embodiments of the present disclosure have been discussed above through illustration of the embodiments and modified examples thereof. However, the power amplification systems and DPD methods according to embodiments of the disclosure are not restricted to the above-described embodiments and modified examples thereof. Other embodiments implemented by combining certain elements in the above-described embodiments and modified examples thereof and other modified examples obtained by making various modifications to the above-described embodiments and modified examples thereof by those skilled in the art without departing from the scope and spirit of the disclosure are also encompassed in the disclosure. Various types of equipment integrating the above-described power amplification systems are also encompassed in the disclosure.

For example, in the circuit configurations of various circuits according to the above-described embodiments, another circuit element and another wiring may be inserted onto a path connecting circuit elements and/or a path connecting signal paths illustrated in the drawings. In one example, a filter may be inserted between the DAC 72 and the quadrature modulator 73. In another example, a filter may be inserted between the power amplifier 2 and the antenna 5.

In the above-described embodiments, multiple discrete voltages are supplied from the switched-capacitor circuit to the output switch circuit. However, this configuration is only an example. For instance, multiple voltages may be supplied from the respective DC-to-DC converters. If the voltage levels of multiple discrete voltages are different by equal degrees, the use of a switched-capacitor circuit is preferable, which is effective in reducing the size of a tracker module.

In the above-described embodiments, four discrete voltages are supplied to the power amplifier. However, the number of discrete voltages is not limited to four. For example, if multiple discrete voltages include at least a voltage corresponding to the maximum output power and a voltage corresponding to the most frequently generated output power, the power-added efficiency can be improved.

The present disclosure can be widely used for communication equipment, such as a cellular phone, as a power amplification system for amplifying a radio-frequency signal.

What is claimed is:

1. A power amplification system comprising:
a first power amplifier;
an output switch circuit configured to selectively output at least one of multiple discrete voltages as a first power supply of the first power amplifier, the first power supply being provided from the output switch circuit to the first power amplifier by a first path;
a filter circuit configured to be connected or disconnected to the first path; and
a digital predistortion circuit configured to generate first distortions in a first input signal of the first power amplifier,
wherein:
(i) when the filter circuit is disconnected to the first path, the digital predistortion circuit is configured to generate the first distortions in the first input signal by using a first mathematical-expression model with a first parameter set, and
(ii) when the filter circuit is connected to the first path, the digital predistortion circuit is configured to generate the first distortions in the first input signal by using a second mathematical-expression model with a second parameter set,
wherein the first parameter set and the second parameter set are at least partially different from each other.

2. The power amplification system according to claim 1,
wherein the filter circuit is a second filter circuit,
the power amplification system further comprises:
a first filter circuit that is configured to be connected or disconnected to the first path, and
wherein:
(i) when the first filter circuit is connected to the first path and the second filter circuit is not connected to the first path, the digital predistortion circuit is configured to generate the first distortions in the first input signal by using the first mathematical-expression model with the first parameter set,
(ii) when both the first filter circuit and the second filter circuit are connected to the first path, the digital predistortion circuit is configured to generate the first distortions in the first input signal by using the second mathematical-expression model with the second parameter set, and
(iii) when the first filter circuit is not connected to the first path and the second filter circuit is connected to the first path, the digital predistortion circuit is configured to generate the first distortions in the first input signal by using a third mathematical-expression model with a third parameter set,
wherein the first parameter set, the second parameter set, and the third parameter set are at least partially different from each other.

3. The power amplification system according to claim 2, wherein:
the first filter circuit is connected between the output switch circuit and the first power amplifier,
the second filter circuit is connected between the output switch circuit and the first power amplifier in parallel with the first filter circuit, and
the power amplification system further comprises:
a first switch connected with the first filter circuit, and being switched to connect or disconnect the first filter circuit between the output switch circuit and the first power amplifier; and
a second switch connected with the second filter circuit, and being switched to connect or disconnect the second filter circuit between the output switch circuit and the first power amplifier.

4. The power amplification system according to claim 2, wherein:
the first filter circuit is connected between the first path and a ground,
the second filter circuit is connected between the first path and the ground in parallel with the first filter circuit, and
the power amplification system further comprises:
a first switch connected with the first filter circuit, and being configured to connect or disconnect the first filter circuit between the first path and the ground; and
a second switch connected with the second filter circuit, and being configured to connect or disconnect the second filter circuit between the first path and the ground.

5. The power amplification system according to claim 1, wherein:
the filter circuit is a second filter circuit,
the power amplification system further comprises:
a first filter circuit; and
a second power amplifier,
the output switch circuit is configured to selectively output the at least one of the multiple discrete voltages as a second power supply of the second power amplifier, the second power supply being provided from the output switch circuit to the second power amplifier by a second path,
the first filter circuit is connected to the first path and the second path,
the second filter circuit is configured to be connected or disconnected to the first path and/or the second path, and
wherein:
(i) when the first power amplifier amplifies the first input signal and the second filter circuit is disconnected to the first path, the digital predistortion circuit is configured to generate the first distortions in the first input signal by using the first mathematical-expression model with the first parameter set,
(ii) when the first power amplifier amplifies the first input signal and the second filter circuit is connected to the first path, the digital predistortion circuit is configured to generate the first distortions in the first input signal by using the second mathematical-expression model with the second parameter set, and
(iii) when the second power amplifier amplifies a second input signal and the second filter circuit is connected to the second path, the digital predistortion circuit is configured to generate second distortions in the second input signal by using a third mathematical-expression model with a third parameter set,
wherein the first parameter set, the second parameter set, and the third parameter set are at least partially different from each other.

6. The power amplification system according to claim 5, wherein:
the first filter circuit is connected between the output switch circuit and the first power amplifier,
the second filter circuit is connected between the output switch circuit and the second power amplifier, and
the power amplification system further comprises:
a first switch connected with the second filter circuit and being switched to connect or disconnect the second filter circuit to the output switch circuit.

7. The power amplification system according to claim 5, wherein:
the first filter circuit is connected between the first path and a ground,
the second filter circuit is connected between the second path and the ground, and
the power amplification system further comprises:
a first switch connected with the second filter circuit, and being switched to connect or disconnect the second filter circuit to the second path.

8. The power amplification system according to claim 1, wherein:
the filter circuit is a second filter circuit,
the power amplification system further comprises:
a first filter circuit;
a second power amplifier;
a third power amplifier; and
a third filter circuit,
the output switch circuit is configured to selectively output the at least one of the multiple discrete voltages as a second power supply to the second power amplifier, and as a third power supply to the third power amplifier, the second power supply being provided from the output switch circuit to the second power amplifier by a second path, the third power supply being provided from the output switch circuit to the third power amplifier by a third path,
the first filter circuit is connected to the first path, the second path and the third path,
the second filter circuit is configured to be connected or disconnected to the second path and the third path,
the third filter circuit is configured to be connected or disconnected to the first path, the second path and the third path,
wherein:
(i) when the first power amplifier amplifies the first input signal, and the second filter circuit and the third filter circuit are not connected to the first path, the digital predistortion circuit is configured to generate the first distortions in the first input signal by using the first mathematical-expression model with the first parameter set,
(ii) when the first power amplifier amplifies the first input signal, the second filter circuit is connected to the first path and the third filter circuit is not connected to the first path, the digital predistortion circuit is configured to generate the first distortions in the first input signal by using the second mathematical-expression model with the second parameter set,
(iii) when the first power amplifier amplifies the first input signal, the second filter circuit is not connected to the first path and the third filter circuit is connected to the first path, the digital predistortion circuit is configured to generate the first distortions in the first input signal by a third mathematical-expression model with a third parameter set,
(iv) when the first power amplifier amplifies the first input signal, the second filter circuit and the third filter circuit are connected to the first path, the digital predistortion circuit is configured to generate the first distortions in the first input signal by using a fourth mathematical-expression model with a fourth parameter set,
(v) when the second power amplifier amplifies a second input signal, the second filter circuit is connected to the second path and when the third filter circuit is not connected to the second path, the digital predistortion circuit is configured to generate second distortions in the second input signal by using a fifth mathematical-expression model with a fifth parameter set,
(vi) when the second power amplifier amplifies a second input signal, and the second filter circuit and the third filter circuit are connected to the second path, the digital predistortion circuit is configured to generate the second distortions in the second input signal by using a sixth mathematical-expression model with a sixth parameter set,
(vii) when the third power amplifier amplifies a third input signal, the second filter circuit is not connected to the third path and the third filter circuit is connected to the third path, the digital predistortion circuit is configured to generate third distortions in the third input signal by using a seventh mathematical-expression model with a seventh parameter set, and
(viii) when the third power amplifier amplifies a third input signal, and the second filter circuit and the third filter circuit are connected to the third path, the digital predistortion circuit is configured to generate the third distortions in the third input signal by using an eighth mathematical-expression model with an eighth parameter set,
wherein the first parameter set, the second parameter set, the third parameter set, the fourth parameter set, the fifth parameter set, the sixth parameter set, the seventh parameter set, and the eighth parameter set are at least partially different from each other.

9. The power amplification system according to claim 8, wherein:
the first filter circuit is connected between the output switch circuit and the first power amplifier,
the second filter circuit is connected between the output switch circuit and the second power amplifier,
the third filter circuit is connected between the output switch circuit and the third power amplifier, and
the power amplification system further comprises:
a first switch connected with the second filter circuit and being switched to connect or disconnect the second filter circuit to the output switch circuit; and
a second switch connected with the third filter circuit, and being switched to connect or disconnect the third filter circuit to the output switch circuit.

10. The power amplification system according to claim 8, wherein:
the first filter circuit is connected between the first path and a ground,
the second filter circuit is connected between the second path and the ground,
the third filter circuit is connected between the third path and the ground, and
the power amplification system further comprises:
a first switch connected with the second filter circuit, and being switched to connect or disconnect the second filter circuit to the second path; and
a second switch connected with the third filter circuit, and being switched to connect or disconnect the third filter circuit to the third path.

11. The power amplification system according to claim 1, wherein the filter circuit is connected between the output switch circuit and the first power amplifier,
the power amplification system further comprises:
a first switch connected with the filter circuit and being switched to connect or disconnect the filter circuit to the output switch circuit; and
a second switch connected with the output switch circuit and the first power amplifier, and being switched on to bypass the filter circuit.

12. The power amplification system according to claim 1, wherein the digital predistortion circuit is configured to generate a predistorted digital IQ signal with digital distortions, the predistorted digital IQ signal being converted to the first input signal of the first power amplifier with the first distortions, the first input signal being a radio-frequency signal.

13. A digital predistortion method comprising:
determining a mathematical-expression model for digital predistortion and a parameter set associated with the mathematical-expression model, based on an attenuation band of a filter circuit with a variable filtering characteristic, the filter circuit being connected between an output switch circuit and a power amplifier, the output switch circuit selectively supplying at least one of multiple discrete voltages as a power supple of the power amplifier; and
generating distortions in an input signal of the power amplifier by using the mathematical-expression model with the parameter set.

14. The digital predistortion method according to claim 13,
wherein the determining the mathematical-expression model and the parameter set comprises:
determining a first mathematical-expression model for digital predistortion and a first parameter set associated with the first mathematical-expression model when the attenuation band of the filter circuit is wider than a threshold band, and
determining a second mathematical-expression model for digital predistortion and a second parameter set associated with the second mathematical-expression model when the attenuation band of the filter circuit is not wider than the threshold band, the second parameter set including fewer parameters than the first parameter set.

15. The digital predistortion method according to claim 13, wherein the generating the distortions in the input signal comprises:
generating digital distortions in a predistorted digital IQ signal by using the mathematical-expression model with the parameter set, the predistorted digital IQ signal being converted to the input signal of the power amplifier with the distortions, the input signal being a radio-frequency signal.

16. A digital predistortion circuit,
wherein:
(i) when a filter circuit is disconnected to a first path that provides a first power supply from an output switch circuit to a first power amplifier, the output switch circuit selectively outputting at least one of multiple discrete voltages as the first power supply to the first power amplifier, the digital predistortion circuit is configured to generate first distortions in a first input signal of the first power amplifier by using a first mathematical-expression model with a first parameter set, and
(ii) when the filter circuit is connected to the first path, the digital predistortion circuit is configured to generate the first distortions in the first input signal by using a second mathematical-expression model with a second parameter set,
wherein the first parameter set and the second parameter set are at least partially different from each other.

17. The digital predistortion circuit according to claim 16,
wherein: the filter circuit is a second filter circuit,
wherein:
(i) when a first filter circuit is connected to the first path and the second filter circuit is not connected to the first path, the digital predistortion circuit is configured to generate the first distortions in the first input signal by using the first mathematical-expression model with the first parameter set,
(ii) when both the first filter circuit and the second filter circuit are connected to the first path, the digital predistortion circuit is configured to generate the first distortions in the first input signal by using the second mathematical-expression model with the second parameter set, and
(iii) when the first filter circuit is not connected to the first path and the second filter circuit is connected to the first path, the digital predistortion circuit is configured to generate the first distortions in the first input signal by using a third mathematical-expression model with a third parameter set,
wherein the first parameter set, the second parameter set, and the third parameter set are at least partially different from each other.

18. The digital predistortion circuit according to claim 16,
wherein:
the filter circuit is a second filter circuit,
the output switch circuit selectively outputs the at least one of multiple discrete voltages as a second power supply to a second power amplifier by a second path, and
a first filter circuit is connected to the first path and the second path,
wherein:
(i) when the first power amplifier amplifies the first input signal and the second filter circuit is not connected to the first path, the digital predistortion circuit is configured to generate the first distortions in the first input signal by using the first mathematical-expression model with the first parameter set,
(ii) when the first power amplifier amplifies the first input signal and the second filter circuit is connected to the first path, the digital predistortion circuit is configured to generate the first distortions in the first input signal by using the second mathematical-expression model with the second parameter set, and
(iii) when the second power amplifier amplifies a second input signal and the second filter circuit is connected to the second path, the digital predistortion circuit is configured to generate second distortions in the second input signal by using a third mathematical-expression model with a third parameter set, and
wherein the first parameter set, the second parameter set, and the third parameter set are at least partially different from each other.

19. The digital predistortion circuit according to claim 16,
wherein:
the filter circuit is a second filter circuit,
the output switch circuit selectively outputs the at least one of multiple discrete voltages as a second power supply to a second power amplifier by a second path and selectively outputs the at least one of multiple discrete voltages as a third power supply to a third power amplifier by a third path, and
a first filter circuit is connected to the first path, the second path, and the third path,
wherein:
(i) when the first power amplifier amplifies the first input signal and both the second filter circuit and a third filter circuit are disconnected to the first path, the digital predistortion circuit is configured to generate the first distortions in the first input signal by using the first mathematical-expression model with the first parameter set,
(ii) when the first power amplifier amplifies the first input signal, the second filter circuit is connected to the first path and the third filter circuit is disconnected to the first path, the digital predistortion circuit is configured to generate the first distortions in the first input signal by using the second mathematical-expression model with the second parameter set,
(iii) when the first power amplifier amplifies the first input signal, the second filter circuit is not connected to the first path and the third filter circuit is connected to the first path, the digital predistortion circuit is configured to generate the first distortions in the first input signal by using a third mathematical-expression model with a third parameter set,
(iv) when the first power amplifier amplifies the first input signal, and both the second filter circuit and the third filter circuit are connected to the first path, the digital predistortion circuit is configured to generate the first distortions in the first input signal by using a fourth mathematical-expression model with a fourth parameter set,
(v) when the second power amplifier amplifies a second input signal, the second filter circuit is connected to the second path and the third filter circuit is disconnected to the second path, the digital predistortion circuit is configured to generate second distortions in the second input signal by using a fifth mathematical-expression model with a fifth parameter set,
(vi) when the second power amplifier amplifies the second input signal, both the second filter circuit and the third filter circuit are connected to the second path, the digital predistortion circuit is configured to generate the second distortions in the second input signal by using a sixth mathematical-expression model with a sixth parameter set,
(vii) when the third power amplifier amplifies a third input signal, the second filter circuit is disconnected to the third path and the third filter circuit is connected to the third path, the digital predistortion circuit is configured to generate third distortions in the third input signal by using a seventh mathematical-expression model with a seventh parameter set, and
(viii) when the third power amplifier amplifies a third input signal, and the second filter circuit and the third filter circuit are connected to the third path, the digital predistortion circuit is configured to generate the third distortions in the third input signal by using an eighth mathematical-expression model with an eighth parameter set, and
wherein the first parameter set, the second parameter set, the third parameter set, the fourth parameter set, the fifth parameter set, the sixth parameter set, the seventh parameter set, and the eighth parameter set are at least partially different from each other.

20. The digital predistortion circuit according to claim 16, wherein the digital predistortion circuit is configured to generate a predistorted digital IQ signal with digital distortions, the predistorted digital IQ signal being converted to the first input signal of the first power amplifier with the first distortions, the first input signal being a radio-frequency signal.
